(19) United States
(12) Patent Application Publication
(10) Pub. No.: US 2026/0206661 A1
(43) Pub. Date: Jul. 16, 2026

(54) STRUCTURES AND METHODS FOR LOCAL HEATING OF HYBRID BONDING CONTACT

(71) Applicant: ADEIA SEMICONDUCTOR BONDING TECHNOLOGIES INC., San Jose, CA (US)

(72) Inventors: Cyprian Emeka Uzoh, San Jose, CA (US); Dominik Suwito, San Jose, CA (US); Pawel Mrozek, San Jose, CA (US); Rajan Gangadharan, San Jose, CA (US); Bongsub Lee, Santa Clara, CA (US)

(21) Appl. No.: 19/023,008

(22) Filed: Jan. 15, 2025

(51) Int. Cl. H01L 23/00

(52) U.S. Cl. CPC H10W 99/00; H10W 72/019; H10W 72/90; H10W 72/01935; H10W 72/923; H10W 72/952; H10W 72/953; H10W 80/312; H10W 80/327; H10W 80/338; H10W 90/792

(57) ABSTRACT

Methods and structures facilitate hybrid bonding by selective local heating of the hybrid bonding interface. Inclusion of magnetic material can facilitate inductively heating features at the hybrid bonding interface. Inclusion of microwave-susceptible material can facilitate microwave heating of features at the hybrid bonding interface.

### BACKGROUND

### Field

The field relates to microelectronic elements, bonded structures, and methods of forming bonded structures, that include direct metal bonds between opposing conductive features.

### Description of the Related Art

Microelectronic elements, such as integrated device dies or chips, may be mounted or stacked on other elements thereby forming a bonded structure. Direct metal bonding can be conducted at low temperatures and without external pressure. For example, direct hybrid bonding involves directly bonding non-conductive features (e.g., inorganic dielectrics) of different elements together, with a dielectric-to-dielectric direct bond and without an adhesive, while also directly bonding conductive features (e.g., metal pads or lines) of the elements together. For example, a microelectronic element can be mounted to a carrier, such as an interposer, a reconstituted wafer or element, etc. As another example, a microelectronic element can be stacked on top of another microelectronic element, e.g., a first integrated device die can be stacked on a second integrated device die. Each of the microelectronic elements can have conductive pads for mechanically and electrically bonding the elements to one another. There is a continuing need for improved methods for forming the bonded structure.

### BRIEF DESCRIPTION OF THE DRAWINGS

FIG. 1A is a schematic side sectional view of two elements before being directly bonded, according to an embodiment.

FIG. 1B is a schematic side sectional view of the two elements of FIG. 1A after being directly bonded, according to an embodiment.

FIG. 2 is a flowchart illustrating a process of forming a bonded structure that includes inductively heating microelectronic elements, according to some embodiments.

FIGS. 3A-3D are schematic side sectional views of microelectronic elements that include a magnetic material at various blocks of a process like that shown in FIG. 2.

FIGS. 4A-4D are schematic side sectional views of microelectronic elements having magnetic layers, according to some embodiments.

FIGS. 5A-5C are schematic side sectional views of microelectronic elements having magnetic particles, according to some embodiments.

FIG. 6 is a flowchart illustrating a process of forming a bonded structure that includes microwave heating microelectronic elements, according to some embodiments.

FIGS. 7A-7D are schematic side sectional views of microelectronic elements that include a microwave susceptible material at various blocks of a process like that shown in FIG. 6.

FIGS. 8A and 8B are schematic side sectional views of microelectronic elements having microwave susceptible layers, according to some embodiments.

FIGS. 9A-9C are schematic side sectional views of microelectronic elements having microwave susceptible particles, according to some embodiments.

### DETAILED DESCRIPTION

Various embodiments disclosed herein relate to directly bonded structures in which two or more elements can be directly bonded to one another without an intervening adhesive. Such processes and structures are referred to herein as “direct bonding” processes or “directly bonded” structures. Direct bonding can involve bonding of one material on one element and one material on the other element (also referred to as “uniform” direct bond herein), where the materials on the different elements need not be the same, without traditional adhesive materials. Direct bonding can also involve bonding of multiple materials on one element to multiple materials on the other element (e.g., hybrid bonding).

In some implementations (not illustrated), each bonding layer has one material. In these uniform direct bonding processes, only one material on each element is directly bonded. Example uniform direct bonding processes include the ZIBOND® techniques commercially available from Adeia of San Jose, CA. The materials of opposing bonding layers on the different elements can be the same or different, and may comprise elemental or compound materials. For example, in some embodiments, nonconductive bonding layers can be blanket deposited over the base substrate portions without being patterned with conductive features (e.g., without pads). In other embodiments, the bonding layers can be patterned on one or both elements, and can be the same or different from one another, but one material from each element is directly bonded without adhesive across surfaces of the elements (or across the surface of the smaller element if the elements are differently-sized). In another implementation of uniform direct bonding, one or both of the nonconductive bonding layers may include one or more conductive features, but the conductive features are not involved in the bonding. For example, in some implementations, opposing nonconductive bonding layers can be uniformly directly bonded to one another, and through substrate vias (TSVs) can be subsequently formed through one element after bonding to provide electrical communication to the other element.

In various embodiments, the bonding layers 108a and/or 108b can comprise a non-conductive material such as a dielectric material or an undoped semiconductor material, such as undoped silicon, which may include native oxide. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. In some embodiments, the dielectric materials at the bonding surface do not comprise polymer materials, such as epoxy (e.g., epoxy adhesives, cured epoxies, or epoxy composites such as FR-4 materials), resin or molding materials.

In other embodiments, the bonding layers can comprise an electrically conductive material, such as a deposited conductive oxide material, e.g., indium tin oxide (ITO), as disclosed in U.S. patent application Ser. No. 18/391,173, filed Dec. 20, 2023, the entire contents of which is incorporated by reference herein in its entirety for providing examples of conductive bonding layers without shorting contacts through the interface.

In direct bonding, first and second elements can be directly bonded to one another without an adhesive, which is different from a deposition process and results in a structurally different interface compared to that produced by deposition. In one application, a width of the first element in the bonded structure is similar to a width of the second element. In some other embodiments, a width of the first element in the bonded structure is different from a width of the second element. The width or area of the larger element in the bonded structure may be at least 10% larger than the width or area of the smaller element. Further, the interface between directly bonded structures, unlike the interface beneath deposited layers, can include a defect region in which nanometer-scale voids (nanovoids) are present. The nanovoids may be formed due to activation of one or both of the bonding surfaces (e.g., exposure to a plasma, explained below).

The bond interface between non-conductive bonding surfaces can include a higher concentration of materials from the activation and/or last chemical treatment processes compared to the bulk of the bonding layers. For example, in embodiments that utilize a nitrogen plasma for activation, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH₂ molecules, yielding a nitrogen-terminated surface. In embodiments that utilize an oxygen plasma for activation, an oxygen concentration peak can be formed at the bond interface between non-conductive bonding surfaces. In some embodiments, the bond interface can comprise silicon oxynitride, silicon oxycarbonitride, or silicon carbonitride. The direct bond can comprise a covalent bond, which is stronger than van Der Waals bonds. The bonding layers can also comprise polished surfaces that are planarized to a high degree of smoothness.

In direct bonding processes, such as uniform direct bonding and hybrid bonding, two elements are bonded together without an intervening adhesive. In non-direct bonding processes that utilize an adhesive, an intervening material is typically applied to one or both elements to effectuate a physical connection between the elements. For example, in some adhesive-based processes, a flowable adhesive (e.g., an organic adhesive, such as an epoxy), which can include conductive filler materials, can be applied to one or both elements and cured to form the physical connection between elements.

By contrast, direct bonding processes join two elements by forming strong chemical bonds (e.g., covalent bonds) between opposing nonconductive materials. For example, in direct bonding processes between nonconductive materials, one or both nonconductive surfaces of the two elements are planarized and chemically prepared (e.g., activated and/or terminated) such that when the elements are brought into contact, strong chemical bonds (e.g., covalent bonds) are formed, which are stronger than Van der Waals or hydrogen bonds. In some implementations (e.g., between opposing dielectric surfaces, such as opposing silicon oxide surfaces), the chemical bonds can occur spontaneously at room temperature upon being brought into contact. In some implementations, the chemical bonds between opposing non-conductive materials can be strengthened after annealing the elements.

As noted above, hybrid bonding is a species of direct bonding in which both non-conductive features directly bond to non-conductive features, and conductive features directly bond to conductive features of the elements being bonded. The non-conductive bonding materials and interface can be as described above, while the conductive bond can be formed, for example, as a direct metal-to-metal connection. In one example conventional metal bonding process, a fusible metal alloy (e.g., solder) can be provided between the conductors of two elements, heated to melt the alloy, and cooled to form the connection between the two elements. The resulting bond often evinces sharp interfaces with conductors from both elements, and is subject to reversal by reheating. By way of contrast, direct metal bonding as employed in hybrid bonding does not require melting or an intermediate fusible metal alloy, and can result in strong mechanical and electrical connections, often demonstrating interdiffusion of the bonded conductive features with grain growth across the bonding interface between the elements, even without the much higher temperatures and pressures of thermocompression bonding.

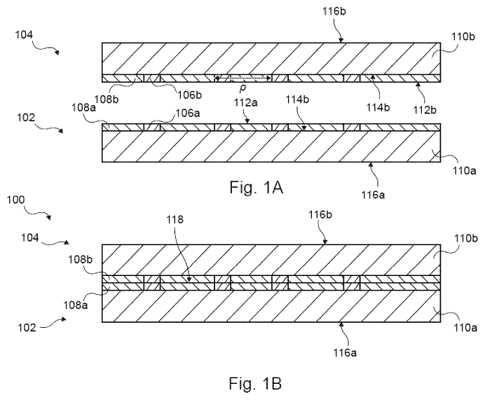

FIGS. 1A and 1B schematically illustrate cross-sectional side views of first and second elements 102, 104 prior to and after, respectively, a process for forming a directly bonded structure, and more particularly a hybrid bonded structure, according to some embodiments. In FIG. 1B, a bonded structure 100 comprises the first and second elements 102 and 104 that are directly bonded to one another at a bond interface 118 without an intervening adhesive. Conductive features 106a of a first element 102 may be electrically connected to corresponding conductive features 106b of a second element 104. In the illustrated hybrid bonded structure 100, the conductive features 106a are directly bonded to the corresponding conductive features 106b without intervening solder or conductive adhesive.

The conductive features 106a and 106b of the illustrated embodiment are embedded in, and can be considered part of, a first bonding layer 108a of the first element 102 and a second bonding layer 108b of the second element 104, respectively. Field regions of the bonding layers 108a, 108b extend between and partially or fully surround the conductive features 106a, 106b. The bonding layers 108a, 108b can comprise layers of non-conductive materials suitable for direct bonding, as described above, and the field regions are directly bonded to one another without an adhesive. The non-conductive bonding layers 108a, 108b can be disposed on respective front sides 114a, 114b of base substrate portions 110a, 110b.

The first and second elements 102, 104 can comprise microelectronic elements, such as semiconductor elements, including, for example, integrated device dies, wafers, passive devices, discrete active devices such as power switches, MEMS, etc. In some embodiments, the base substrate portion can comprise a device portion, such as a bulk semiconductor (e.g., silicon) portion of the elements 102, 104, and back-end-of-line (BEOL) interconnect layers over such semiconductor portions. The bonding layers 108a, 108b can be provided as part of such BEOL layers during device fabrication, as part of redistribution layers (RDL), or as specific bonding layers added to existing devices, with bond pads extending from underlying contacts. Active devices and/or circuitry can be patterned and/or otherwise disposed in or on the base substrate portions 110a, 110b, and can electrically communicate with at least some of the conductive features 106a, 106b. Active devices and/or circuitry (not shown) can be disposed at or near the front sides 114a, 114b of the base substrate portions 110a, 110b, and/or at or near opposite backsides 116a, 116b of the base substrate portions 110a, 110b. In other embodiments, one or both of the elements 102, 104 may not include active circuitry, but may instead comprise dummy elements, passive interposers, passive optical elements (e.g., glass substrates, gratings, lenses), etc. The bonding layers 108a, 108b are shown as being provided on the front sides of the elements, but similar bonding layers can be additionally or alternatively provided on the back sides of the elements.

In some embodiments, the base substrate portions 110a, 110b can have significantly different coefficients of thermal expansion (CTEs), and bonding elements that include such different based substrate portions can form a heterogenous bonded structure. The CTE difference between the base substrate portions 110a and 110b, and particularly between bulk semiconductor (typically single crystal) portions of the base substrate portions 110a, 110 b, can be greater than 5 ppm/° C. or greater than 10 ppm/° C. For example, the CTE difference between the base substrate portions 110a and 110b can be in a range of 5 ppm/° C. to 100 ppm/° C., 5 ppm/° C. to 40 ppm/° C., 10 ppm/° C. to 100 ppm/° C., or 10 ppm/° C. to 40 ppm/° C.

In some embodiments, one of the base substrate portions 110a, 110b can comprise optoelectronic single crystal materials, including perovskite materials, that are useful for optical piezoelectric or pyroelectric applications, and the other of the base substrate portions 110a, 110b comprises a more conventional substrate material. For example, one of the base substrate portions 110a, 110b comprises lithium tantalate (LiTaO₃) or lithium niobate (LiNbO₃), and the other one of the base substrate portions 110a, 110b comprises silicon (Si), quartz, fused silica glass, sapphire, or a glass. In other embodiments, one of the base substrate portions 110a, 110b comprises a III-V single semiconductor material, such as gallium arsenide (GaAs) or gallium nitride (GaN), and the other one of the base substrate portions 110a, 110b can comprise a non-III-V semiconductor material, such as silicon (Si), or can comprise other materials with similar CTE, such as quartz, fused silica glass, sapphire, or a glass. In still other embodiments, one of the base substrate portions 110a, 110b comprises a semiconductor material and the other of the base substrate portions 110a, 110b comprises other materials, such as a glass, organic or ceramic substrate.

In some arrangements, the first element 102 can comprise a singulated element, such as a singulated integrated device die. In other arrangements, the first element 102 can comprise a carrier or substrate (e.g., a semiconductor wafer) that includes a plurality (e.g., tens, hundreds, or more) of device regions that, when singulated, forms a plurality of integrated device dies, though in other embodiments such a carrier can be a package substrate (e.g., a laminate substrate, a ceramic substrate, etc.) or a passive or active interposer. Similarly, the second element 104 can comprise a singulated element, such as a singulated integrated device die. In other arrangements, the second element 104 can comprise a carrier or substrate (e.g., a semiconductor wafer). The embodiments disclosed herein can accordingly apply to wafer-to-wafer (W2W), die-to-die (D2D), or die-to-wafer (D2W) bonding processes. In W2W processes, two or more wafers can be directly bonded to one another (e.g., direct hybrid bonded) and singulated using a suitable singulation process. After singulation, side edges of the singulated structure (e.g., the side edges of the two bonded elements) can be substantially flush (substantially aligned x-y dimensions) and/or the edges of the bonding layers for both bonded and singulated elements can be coextensive, and may include markings indicative of the common singulation process for the bonded structure (e.g., saw markings if a saw singulation process is used).

While only two elements 102, 104 are shown, any suitable number of elements can be stacked in the bonded structure 100. For example, a third element (not shown) can be stacked on the second element 104, a fourth element (not shown) can be stacked on the third element, and so forth. In such implementations, through substrate vias (TSVs) can be formed to provide vertical electrical communication between and/or among the vertically-stacked elements. Additionally or alternatively, one or more additional elements (not shown) can be stacked laterally adjacent one another along the first element 102. In some embodiments, a laterally stacked additional element may be smaller than the second element. In some embodiments, the bonded structure can be encapsulated with an insulating material, such as an inorganic dielectric (e.g., silicon oxide, silicon nitride, silicon oxynitrocarbide, etc.). One or more insulating layers can be provided over the bonded structure. For example, in some implementations, a first insulating layer can be conformally deposited over the bonded structure, and a second insulating layer (which may include the same material as the first insulating layer, or a different material) can be provided over the first insulating layer.

To effectuate direct bonding between the bonding layers 108a, 108b, the bonding layers 108a, 108b can be prepared for direct bonding. Non-conductive bonding surfaces 112a, 112b at the upper or exterior surfaces of the bonding layers 108a, 108b can be prepared for direct bonding by polishing, for example, by chemical mechanical polishing (CMP). The roughness of the polished bonding surfaces 112a, 112b can be less than 30 A rms. For example, the roughness of the bonding surfaces 112a and 112b can be in a range of about 0.1 Å rms to 15 Å rms, 0.5 Å rms to 10 Å rms, or 1 Å rms to 5 Å rms. Polishing can also be tuned to leave the conductive features 106a, 106b recessed relative to the field regions of the bonding surface 112a, 112b.

Preparation for direct bonding can also include cleaning and exposing one or both of the bonding surfaces 112a, 112b to a plasma and/or etchants to activate at least one of the surfaces 112a, 112b. In some embodiments, one or both of the surfaces 112a, 112b can be terminated with a species after activation or during activation (e.g., during the plasma and/or etch processes). Without being limited by theory, in some embodiments, the activation process can be performed to break chemical bonds at the bonding surface(s) 112a, 112b, and the termination process can provide additional chemical species at the bonding surface(s) 112a, 112b that alters the chemical bond and/or improves the bonding energy during direct bonding. In some embodiments, the activation and termination are provided in the same step, e.g., a plasma to activate and terminate the surface(s) 112a, 112b. In other embodiments, one or both of the bonding surfaces 112a, 112b can be terminated in a separate treatment to provide the additional species for direct bonding. In various embodiments, the terminating species can comprise nitrogen. For example, in some embodiments, the bonding surface(s) 112a, 112b can be exposed to a nitrogen-containing plasma. Other terminating species can be suitable for improving bonding energy, depending upon the materials of the bonding surfaces 112a, 112b. Further, in some embodiments, the bonding surface(s) 112a, 112b can be exposed to fluorine. For example, there may be one or multiple fluorine concentration peaks at or near a bond interface 118 between the first and second elements 102, 104. Typically, fluorine concentration peaks occur at interfaces between material layers. Additional examples of activation and/or termination treatments may be found in U.S. Pat. No. 9,391,143 at Col. 5, line 55 to Col. 7, line 3; Col. 8, line 52 to Col. 9, line 45; Col. 10, lines 24-36; Col. 11, lines 24-32, 42-47, 52-55, and 60-64; Col. 12, lines 3-14, 31-33, and 55-67; Col. 14, lines 38-40 and 44-50; and 10,434,749 at Col. 4, lines 41-50; Col. 5, lines 7-22, 39, 55-61; Col. 8, lines 25-31, 35-40, and 49-56; and Col. 12, lines 46-61, the activation and termination teachings of which are incorporated by reference herein.

Thus, in the directly bonded structure 100, the bond interface 118 between two non-conductive materials (e.g., the bonding layers 108a, 108b) can comprise a very smooth interface with higher nitrogen (or other terminating species) content and/or fluorine concentration peaks at the bond interface 118. In some embodiments, the nitrogen and/or fluorine concentration peaks may be detected using various types of inspection techniques, such as SIMS techniques. The polished bonding surfaces 112a and 112b can be slightly rougher (e.g., about 1 Å rms to 30 Å rms, 3 Å rms to 20 Å rms, or possibly rougher) after an activation process. In some embodiments, activation and/or termination can result in slightly smoother surfaces prior to bonding, such as where a plasma treatment preferentially smooths out high points on the bonding surface.

The non-conductive bonding layers 108a and 108b can be directly bonded to one another without an adhesive. In some embodiments, the elements 102, 104 are brought together at room temperature, without the need for application of a voltage, and without the need for application of external pressure or force beyond that used to initiate contact between the two elements 102, 104. Contact alone can cause direct bonding between the non-conductive surfaces of the bonding layers 108a, 108b (e.g., covalent dielectric bonding). Subsequent annealing of the bonded structure 100 can cause the conductive features 106a, 106b to directly bond.

In some embodiments, prior to direct bonding, the conductive features 106a, 106b are recessed relative to the surrounding bonding surfaces, such that a total gap between opposing contacts after dielectric bonding and prior to anneal is less than 25 nm, or less than 10 nm. Because the recess depths for the conductive features 106 a and 106 b can vary across each element, due to process variation, the noted gap can represent a maximum or an average gap between corresponding conductive features 106a, 106b of two joined elements (prior to anneal). Upon annealing, the conductive features 106a and 106b can expand and contact one another to form a metal-to-metal direct bond.

During annealing, the conductive features 106a, 106b (e.g., metallic material) can expand while the direct bonds between surrounding non-conductive materials of the bonding layers 108a, 108b resist separation of the elements, such that the thermal expansion increases the internal contact pressure between the opposing conductive features. Annealing can also cause metallic grain growth across the bonding interface, such that grains from one element migrate across the bonding interface at least partially into the other element, and vice versa. Thus, in some hybrid bonding embodiments, opposing conductive materials are joined without heating above the conductive materials'melting temperature. In various embodiments, bonds can form at lower temperatures compared to soldering or thermocompression bonding.

In various embodiments, the conductive features 106a, 106b can comprise discrete pads, contacts, electrodes, or traces at least partially embedded in the non-conductive field regions of the bonding layers 108a, 108b. In some embodiments, the conductive features 106a, 106b can comprise exposed contact surfaces of TSVs (e.g., through silicon vias).

As noted above, in some embodiments, in the elements 102, 104 of FIG. 1A prior to direct bonding, portions of the respective conductive features 106a and 106b can be recessed below the non-conductive bonding surfaces 112a and 112b, for example, recessed by less than 30 nm, less than 20 nm, less than 15 nm, or less than 10 nm, for example, recessed in a range of 2 nm to 20 nm, or in a range of 4 nm to 10 nm. Due to process variation, both dielectric thickness and conductor recess depths can vary across an element. Accordingly, the above recess depth ranges may apply to individual conductive features 106a, 106b or to average depths of the recesses relative to local non-conductive field regions. Even for an individual conductive feature 106a, 106b, the vertical recess can vary across the surface of the feature, and can be measured at or near the lateral middle or center of the cavity in which a given conductive feature 106a, 106b is formed, or can be measured at the sides of the cavity.

Beneficially, the use of hybrid bonding techniques (such as Direct Bond Interconnect, or DBI®, techniques commercially available from Adeia of San Jose, CA) can enable high density of connections between conductive features 106a, 106b across the direct bond interface 118 (e.g., small or fine pitches for regular arrays).

In some embodiments, a pitch p of the conductive features 106a, 106b, such as conductive traces embedded in the bonding surface of one of the bonded elements, may be less than 100 μm, less than 50 μm, less than 20 μm, less than 5 μm, less than 2 μm, or even less than 1 μm. For some applications, the ratio of the pitch of the conductive features 106a and 106b to one of the lateral dimensions (e.g., a diameter) of the conductive feature is less than 20, or less than 10, or less than 5, or less than 3 and sometimes desirably less than 2. In various embodiments, the conductive features 106a and 106b and/or traces can comprise copper or copper alloys, although other metals may be suitable, such as nickel, aluminum, or alloys thereof. The conductive features disclosed herein, such as the conductive features 106a and 106b, can comprise fine-grain metal (e.g., a fine-grain copper). Further, a major lateral dimension (e.g., a pad diameter) can be small as well, e.g., in a range of about 0.25 μm to 30 μm, in a range of about 0.25 μm to 5 μm, or in a range of about 0.5 μm to 5 μm.

For hybrid bonded elements 102, 104, as shown, the orientations of one or more conductive features 106a, 106b from opposite elements can be opposite to one another. As is known in the art, conductive features in general can be formed with close to vertical sidewalls, particularly where directional reactive ion etching (RIE) defines the conductor sidewalls either directly through etching the conductive material or indirectly through etching surrounding insulators in damascene processes. However, some slight taper to the conductor sidewalls can be present, wherein the conductor becomes narrower farther away from the surface initially exposed to the etch. The taper can be even more pronounced when the conductive sidewall is defined directly or indirectly with isotropic wet or dry etching. In the illustrated embodiment, at least one conductive feature 106b in the bonding layer 108b (and/or at least one internal conductive feature, such as a BEOL feature) of the upper element 104 may be tapered or narrowed upwardly, away from the bonding surface 112b. By way of contrast, at least one conductive feature 106a in the bonding layer 108a (and/or at least one internal conductive feature, such as a BEOL feature) of the lower element 102 may be tapered or narrowed downwardly, away from the bonding surface 112a. Similarly, any bonding layers (not shown) on the backsides 116a, 116b of the elements 102, 104 may taper or narrow away from the backsides, with an opposite taper orientation relative to front side conductive features 106a, 106b of the same element.

As described above, in an anneal phase of hybrid bonding, the conductive features 106a, 106b can expand and contact one another to form a metal-to-metal direct bond. In some embodiments, the materials of the conductive features 106a, 106b of opposite elements 102, 104 can interdiffuse during the annealing process. In some embodiments, metal grains grow into each other across the bond interface 118. In some embodiments, the metal is or includes copper, which can have grains oriented along the 111 crystal plane for improved copper diffusion across the bond interface 118. In some embodiments, the conductive features 106a and 106b may include nanotwinned copper grain structure, which can aid in merging the conductive features during anneal. There is substantially no gap between the non-conductive bonding layers 108a and 108b at or near the bonded conductive features 106a and 106b. In some embodiments, a barrier layer may be provided under and/or laterally surrounding the conductive features 106a and 106b (e.g., which may include copper). In other embodiments, however, there may be no barrier layer under the conductive features 106a and 106b.

During the annealing process, the conductive features can be heated to cause the metal that forms the conductive features to expand so that the conductive features form the metal-to-metal direct bond. Where one or both conductive features from opposite elements are recessed relative to surrounding dielectric, the expansion can initially bridge a gap to form contact between the conductive features. To ensure that the conductive features on the opposing the elements contact each other, the annealing temperature is often selected to be sufficiently high to allow the metal (e.g., copper) to plastically deform and expand into contact with one another. However, annealing at too high of a temperature can degrade the performance of the bonded structure due to exceeding the thermal budget of the elements and/or the bonded structure, and can cause problems of differential expansion, especially with heterogenous substrates of significantly different CTEs. Additionally, while annealing can be performed at lower temperatures, such low-temperature annealing can entail excessively long annealing times, which can also exceed the thermal budget of the elements and/or the bonded structure.

Accordingly, there is a continued need for improved hybrid bonding processes and structures that allow for annealing conductive features without excessively high temperatures and/or excessively long annealing times.

### Conductive Features Having Materials With High Relative Magnetic Permeability

To facilitate the annealing process, the conductive features of the elements being bonded can comprise a magnetic material having a high relative magnetic permeability. As discussed in greater detail below, these materials, which are referred to herein as “magnetic materials,” heat up when exposed to an alternating magnetic field while other materials do not get directly heated. The heat generated within the magnetic material can spread by conduction to adjacent features, resulting in localized heating of those features. Accordingly, an induction heating system can be used to heat up conductive features having a magnetic material incorporated into them or adjacent to them, which can cause the conductive feature to expand and contact the opposing conductive feature during the annealing process. However, other portions of the elements being bonded (e.g., typical semiconductor substrate materials, dielectric materials or pure copper features), may not be directly heated by alternating magnetic field generated by an induction heating system. With this arrangement, an induction heating system can be used to anneal the bonded structure without exceeding the thermal budget of the structure because the induction heating may allow for rapid heating of the conductive features being bonded without (or without significantly) heating typical semiconductors, non-magnetic dielectric materials, or the underlying copper features that do not include a magnetic material. For example, active devices (e.g., transistors) remote from the conductive features at the bond interface are not heated nearly as much as the conductive features to be bonded, and thus thermal budgets are saved.

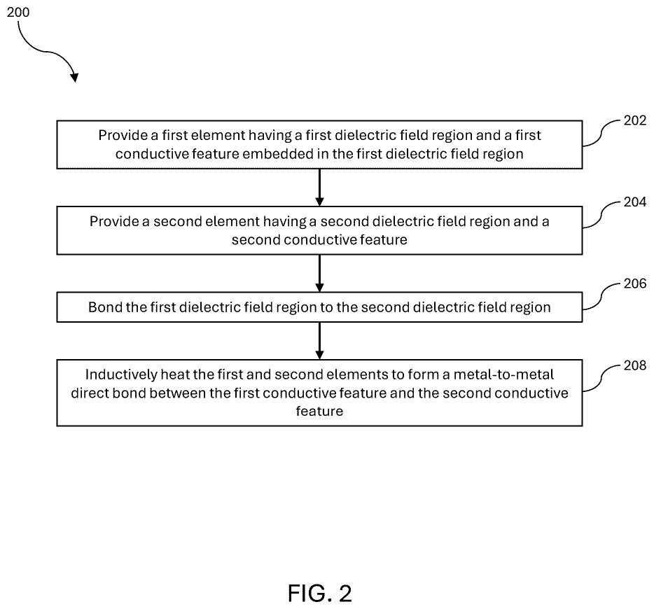

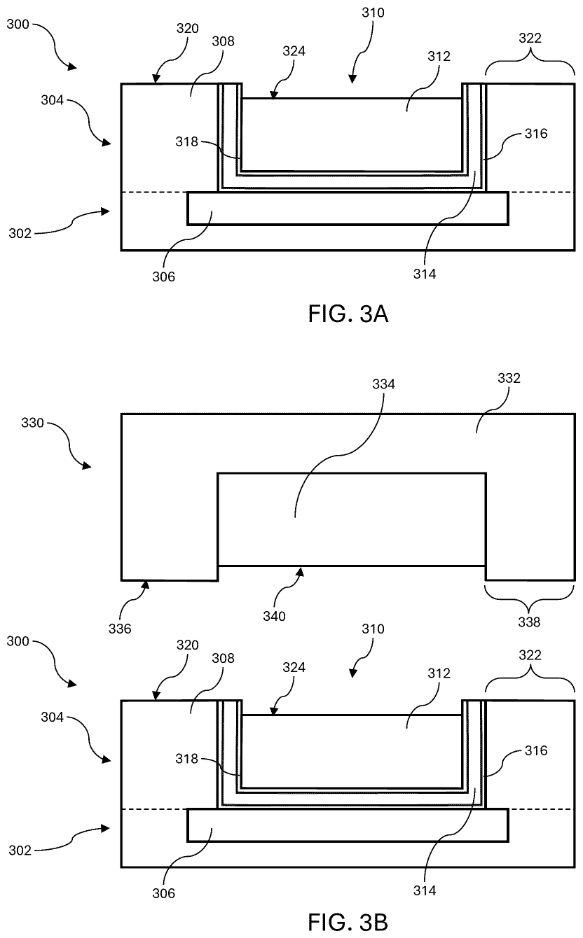

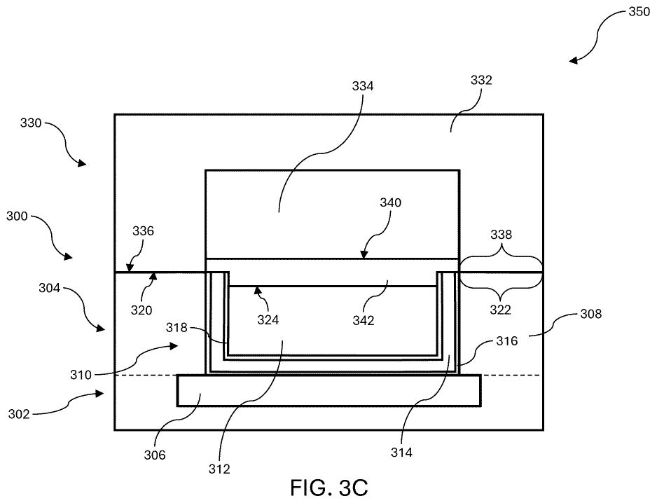

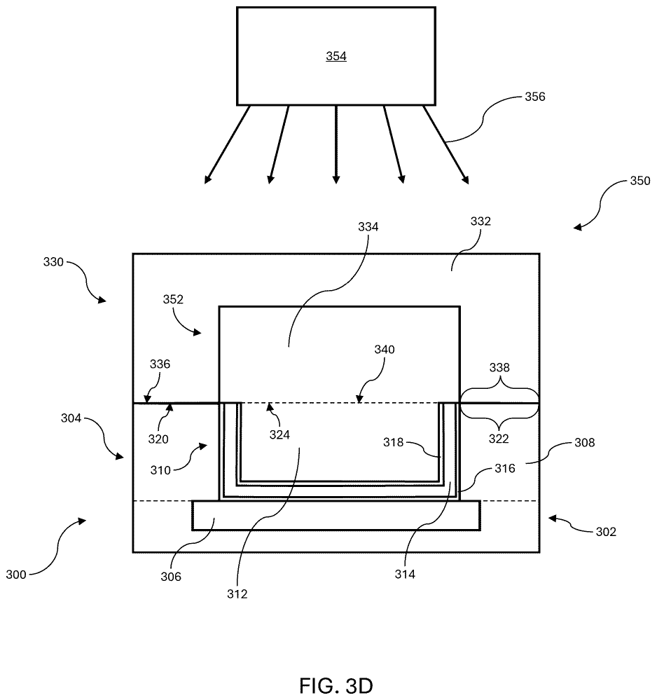

FIG. 2 is a flowchart illustrating a process 200 for forming a bonded microelectronic structure, where the bonded structure includes an element having a conductive feature that includes or is adjacent to a magnetic material. FIGS. 3A-3D are schematic side sectional views of microelectronic elements at various blocks of the process 200 shown in FIG. 2.

Referring to FIGS. 2 and 3A, at block 202, an element 300 is provided. The element 300 comprises a base substrate portion 302 and a bonding layer 304 formed over the base substrate portion 302. The base substrate portion 302 comprises active devices and/or circuitry 306 and the bonding layer 304 comprises a dielectric layer 308 and a conductive feature 310. While not separately illustrated, the skilled artisan will appreciate that the active devices/circuitry 306 can include one or more metallization layers (e.g., BEOL or RDL layers) below the bonding layer 304. The conductive feature 310 comprises a conductive metal 312, a magnetic layer 314, a barrier layer 316, and an adhesion layer 318. In some embodiments, the conductive metal 312 comprises copper. In other elements, the conductive metal 312 comprises a different element, such as nickel or aluminum. In some embodiments, the conductive metal 312 comprises an alloy including one or more of copper and aluminum. The bonding layer 304 has a bonding surface 320 that includes a dielectric field region 322 and a surface 324 of the conductive metal 312 of the conductive feature 310, where the dielectric field region 322 is at least partially formed by the dielectric layer 308. In some embodiments, the bonding surface 320 also comprises surfaces, e.g., edge surfaces, of one or more of the magnetic layer 314, the barrier layer 316, and the adhesion layer 318. In some embodiments, the surface 324 of the conductive metal 312 is recessed below the dielectric field region 322 as shown, although the embodiments are not so limited.

The conductive feature 310 can be formed using a damascene process that includes forming the dielectric layer 308 over or on the base substrate portion 302, patterning the dielectric layer 308 to form a cavity, forming the barrier layer 316 in the cavity to line the bottom surface and sidewalls of the cavity, forming the magnetic layer 314 over the barrier layer 316, forming the adhesion layer 318 over the magnetic layer 314, and then forming the conductive metal 312 over the adhesion layer 318 to at least partially fill the cavity. In some embodiments, one or more of the barrier layer 316, the magnetic layer 314, the adhesion layer 318, and the conductive metal 312 are formed using a deposition process (e.g., a PVD, CVD, ALD, or plating deposition process). In embodiments where the magnetic layer 314 is formed using a plating process, a bottom portion of the magnetic layer 314 (e.g., a portion of the magnetic layer 314 formed near the bottom of the cavity) can be preferentially formed thicker than side portions of the magnetic layer 314. The barrier layer 316 is designed to prevent the conductive metal 312, the magnetic layer 314, and the adhesion layer 318 from diffusing into the dielectric layer 308 during the deposition process. In some arrangements, the barrier layer 316 can comprise titanium (Ti) or tantalum (Ta). For example, the barrier layer 316 can comprise Ti metal and/or TiN or Ta metal and/or TaN. The adhesion layer 318 is designed to improve adhesion between the conductive metal 312 and the dielectric layer 308 and/or the magnetic layer 314. In some embodiments, the adhesion layer 318 comprises Ti. As noted below, depending on selection of the material for the magnetic layer 314, the adhesion layer and/or barrier layer can be omitted. In some embodiments, the barrier layer 316, the adhesion layer 318 and the magnetic layer 314 may comprise similar materials, such as nickel or nickel alloy.

The magnetic layer 314 comprises a magnetic material having a high relative magnetic permeability. As discussed in greater detail below, the element 300 can be exposed to an induction heating system that is configured to generate an alternating magnetic field. When a material having a high relative magnetic permeability is exposed to an alternating magnetic field, the field induces eddy currents within the material, which results in the material heating up (via Joule heating). However, the alternating magnetic field does not induce eddy currents in materials having a low relative magnetic permeability (e.g., copper, silicon oxide, silicon). Accordingly, when the element 300 is exposed to the induction heating system, the magnetic layer 314 can heat up while other portions of the element 300 (e.g., conductive metal 312, dielectric layer 308, base substrate portion 302 including bulk semiconductor material) are not directly heated by the induction heating system. However, the heat given off by the magnetic layer 314 during the induction heating process can spread to adjacent or surrounding structures by conduction. With this arrangement, exposing the element 300 to an induction heating system can allow for the selective and localized heating of the conductive feature 310 during annealing process without heating (or with substantially less heating) of other portions element 300 that are more sensitive to elevated temperatures also being heated.

In some embodiments, the magnetic layer 314 comprises a magnetic material having a relative magnetic permeability of about 3 or greater. For example, in some embodiments, the magnetic layer 314 comprises a magnetic material having a relative magnetic permeability between about 3 and about 100, between about 3 and about 10, between about 10 and about 50, between about 50 and about 100, greater than about 3, greater than about 10, greater than about 50, greater than about 100, or a value in a range defined by any of these values. In some embodiments, the magnetic layer 314 comprises a conductive material, such as a conductive metal or a metal alloy. For example, in some embodiments, the magnetic layer 314 comprises nickel (Ni), a nickel-iron alloy (Ni—Fe), cobalt (Co), a cobalt zirconium alloy (Co—Zr), a cobalt, zirconium, and tantalite alloy (CoZrTa or CZT), Permalloy, superpermalloy, samarium (Sm), neodymium (Nd), or mixtures or alloys of such materials. Where the magnetic layer can also serve a barrier function, such as Ni, the barrier layer 316 can be omitted. Where the magnetic layer can also adhere to the surrounding materials, such as Ni, Ni—Fe, or Permalloy, the adhesion layer 318 can be omitted. In some embodiments, the magnetic layer 314 has a thickness between about 0.05 μm and about 1.0 μm. For example, in some embodiments, the magnetic layer 314 has a thickness between about 0.05 μm about 0.5 um, between about 0.1 μm and 0.2 μm, between about 0.2 μm and about 0.3 μm, between about 0.4 μm and about 0.5 μm, or a value in a range defined by any of these values.

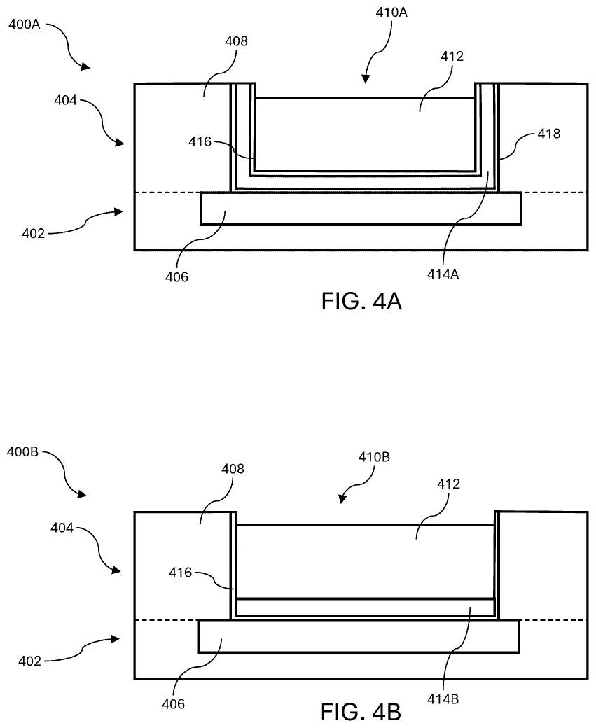

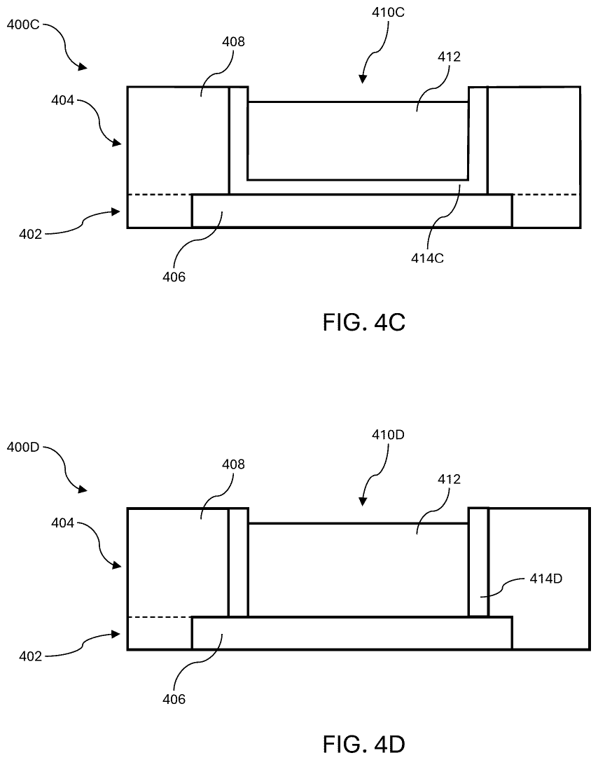

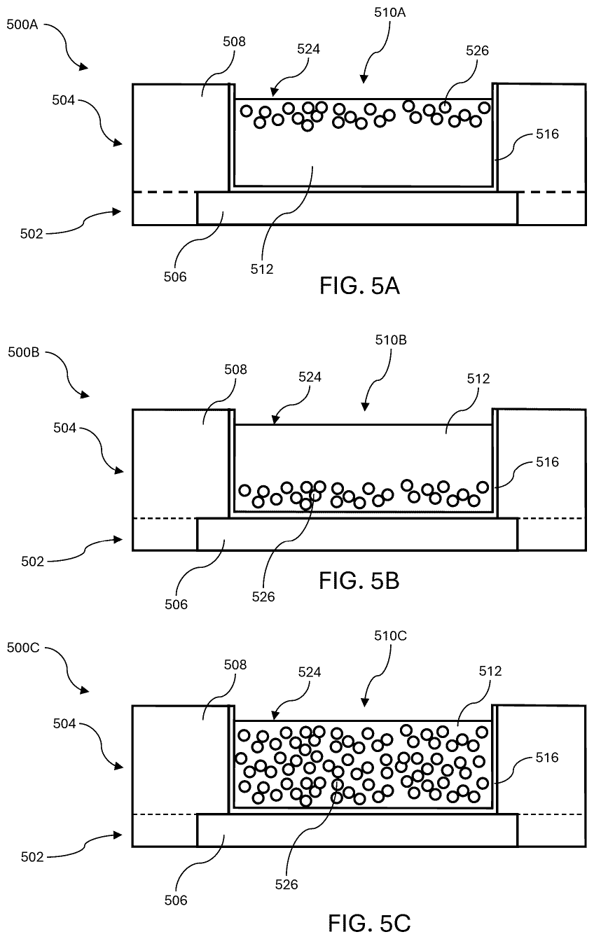

As shown in FIG. 3B, at block 204, a second element 330 is provided. The second element 330 comprises a dielectric layer 332 and a conductive feature 334 and has a bonding surface 336 that includes a dielectric field region 338 and a surface 340 of the conductive feature 334. In some embodiments, the second element 330 has a structure that is generally similar to the structure of element 300. For example, in some embodiments, the conductive feature 334 can include a barrier layer, a magnetic material, an adhesion layer, and a conductive metal formed in a cavity in the dielectric material, where the barrier layer, magnetic material, and adhesion layer line the cavity. In some embodiments, the conductive feature 334 can include the same magnetic material as the magnetic material that the magnetic layer 314 is formed from. In other embodiments, however, the second element 330 can have a structure that is different than the structure of the element 300. For example, in some embodiments, the conductive feature 334 may not include one or more of the barrier layer, the magnetic material, and the adhesion layer. In some embodiments, the conductive feature 334 of the second element 330 can have a structure that is generally similar to that of one of the conductive features 410A-410D shown in FIGS. 4A-4D or conductive features 510A-510C shown in FIGS. 5A-5C. In some embodiments, the conductive feature 334 may not include a magnetic material or may include a second magnetic material that is different from the magnetic material from which the magnetic layer 314 is formed. In some embodiments, including the illustrated embodiment, the surface 340 of the conductive feature 334 can be recessed below the dielectric field region 338. In other embodiments, however, the surface 340 of the conductive feature 334 can be coplanar with the dielectric field region 338. In some embodiments, at least a portion of the surface 340 can protrude past the dielectric field region 338.

As shown in FIG. 3C, at block 206, the dielectric field region 322 of the element 300 is bonded to the dielectric field region 338 of the element 330 to form a bonded structure 350. In some embodiments, the dielectric field region 322 is directly bonded to the dielectric field region 338 with a dielectric-to-dielectric direct bond and without an adhesive. In some embodiments, the dielectric field region 322 is directly bonded to the dielectric field region 338 by bringing the elements 300, 330 together until the dielectric field regions 322, 338 contact each other. In some embodiments, chemical (covalent) bonds between the dielectric field regions 322, 338 can occur spontaneously upon the dielectric field regions being brought into contact with each other, even at room temperature. In some embodiments, the chemical bonds can form without applying a voltage or external pressure or force beyond that used to initiate contact between the two dielectric field regions 322, 338. In some embodiments, bonding the dielectric field region 322 to the dielectric field region 338 comprises planarizing and chemically preparing (e.g., activating and/or terminating) one or both of the dielectric field regions 322, 338.

In some embodiments, bonding the dielectric field region 322 to the dielectric field region 338 does not include heating the first and second elements 300, 330. In other embodiments, however, bonding the dielectric field regions 322, 338 together comprises initially heating the elements 300, 330 after contacting the dielectric field regions 322, 338 together to increase the strength of the chemical bonds between the dielectric field regions 322, 338. In these embodiments, the first and second elements 300, 330 can be heated to a temperature that is high enough to increase the strength of the chemical bonds between the dielectric field regions 322, 338 but that is below the temperature at which the conductive features 310, 334 bond together. For example, in some embodiments, bonding the dielectric field region 322 to the dielectric field region 338 comprises heating the dielectric field regions 322, 338 of the elements 300, 330 to a temperature of 140° C. or less, such as 120° C. Accordingly, after heating the elements 300, 330 during the process of bonding the dielectric field region 322 to the dielectric field region 338, the conductive features 310, 334 are not bonded to each other, and may not contact one another in embodiments in which one or both of the conductive features 310, 334 are recessed below the respective dielectric field regions 322, 338 prior to bonding. Additionally, in embodiments where one or both of the surfaces 324, 340 conductive features 310, 334 are recessed below the respective dielectric field regions 322, 338 prior to bonding, the conductive features 310, 334 may not contact one another even after the elements 300, 330 are initially heated to strengthen dielectric bonds. Accordingly, in these embodiments, after heating the elements 300, 330 during the process of bonding the dielectric field region 322 to the dielectric field region 338, the surfaces 324, 340 can be spaced apart from each other by a gap, as shown in FIG. 3C. In some embodiments, the elements 300, 330 are initially heated using a radiative, a convection, and/or a conductive heating process, such as by use of a standard anneal oven. Typically, such anneals result in the relatively uniform heating of the entire bonded structure 350.

As shown in FIG. 3D, at block 208, the first and second elements 300, 330 are subjected to inductive energy that inductively heats at least the conductive features to form a metal-to-metal direct bond between the first conductive feature 310 and the second conductive feature 334 and to form a conductive interconnection 352 that includes the first and second conductive features 310, 334. The bonded structure 350, including the first and second elements 300, 330, can be inductively heated using an induction heating apparatus 354, which is configured to generate an alternating magnetic field 356. The induction heating apparatus 354 can comprise a chamber into which the bonded structure 350 is placed such that bonded structure 350 is subjected to the alternating magnetic field 356. In some embodiments, the induction heating apparatus 354 includes metal coils on one side of, or surrounding, the chamber in which the bonded structure 350, including the elements 300, 330, is placed. Accordingly, the alternating magnetic field 356 encompasses the elements 300, 330. In some embodiments, the induction heating apparatus 354 comprises more than one coil configured to inductively heat the bonded structure 350.

The alternating magnetic field 356 can penetrate through conventional substrate materials, such as semiconductors, dielectrics and conventional metallization of the bonded structure 350, causing eddy currents to be generated within the electrically conductive materials of the first and second elements 300, 330 that include magnetic materials, which can cause those electrically conductive materials to locally heat up via Joule heating. However, the amount that a given material heats up via Joule heating depends on the characteristics of the material, including its thermal conductivity, electrical resistivity, and magnetic permeability. Copper or aluminum, for example, have very high thermal conductivity, low electrical resistivity, and low magnetic permeability and therefore do not directly heat up significantly due to the alternating magnetic field, such that the conductive metal 312 may not directly heat from the inductive heating. On the other hand, other conductive materials, such as the magnetic layer 314, can have a significantly higher relative magnetic permeability and can rapidly be heated to an elevated temperature by induced eddy currents. Because the magnetic layer 314 is embedded in or closely adjacent the conductive metal 312, however, heat is readily transferred to the conductive metal 312, and to a lesser degree, to surrounding dielectrics. Remote substrate materials, such as bulk semiconductor materials in which active devices are formed, are heated, if at all, by a significantly lower amount.

In some embodiments, subjecting the first and second elements 300, 330 to inductive energy causes the magnetic layer 314 to heat up to a local temperature of between about 400° C. and about 500° C. or more. In other embodiments, however, inductively heating the first and second elements 300, 330 can cause the magnetic layer 314 to be heated to a different temperature. For example, in some embodiments, inductively heating the bonded structure 350 can cause the magnetic layer 314 to be heated to a temperature between about 200° C. and 700° C., such as between about 450° C. and 550° C. In some embodiments, inductively heating the bonded structure 350 comprises inductively heating the bonded structure 350 for a time between about 1 second and about 1800 seconds. The skilled artisan can readily determine an appropriate exposure time through routine experimentation, depending in part on the magnitude of magnetic field in the inductive furnace. Desirably, the local heating does not cause adjacent dielectrics to exceed temperatures at which they can be damaged, such as around 350° C.

The heat generated by the magnetic layer 314 due to the alternating magnetic field 356 spreads to the adjacent metallic materials, such as the barrier layer 316, adhesion layer 318, and conductive metal 312. Accordingly, inductively heating the bonded structure 350 can cause the magnetic layer 314 to rapidly heat up, and because the conductive metal 312 has high thermal conductivity and conducts the heat away from the magnetic layer 314, causes the conductive metal 312 to heat up. For example, in some embodiments, inductively heating the bonded structure 350 can cause the conductive metal 312 to heat up to a local temperature between 200° C. and 250° C. In other embodiments, however, inductively heating the bonded structure 350 can cause the conductive metal 312 to heat up to a different temperature. For example, in some embodiments, inductively heating the bonded structure 350 can cause the conductive feature 310 generally, and the conductive metal 312 in particular, to heat up to a temperature between about 150° C. and 300° C., between about 150° C. and 200° C., between about 200° C. and 250° C., between about 175° C. and 225° C., between about 250° C. and 300° C., a temperature greater than about 300° C., or a value in a range defined by any of these values. In some embodiments, inductively heating the bonded structure 350 can cause the conductive feature 310 to heat up without melting the conductive metal 312 or the magnetic material of the magnetic layer 314.

As the conductive metal 312 heats, it expands toward the second conductive feature 334 until the surface 324 of the conductive metal 312 contacts the surface 340 of the second conductive feature 334 and a metal-to-metal direct bond is formed between the conductive features 310, 334. Accordingly, the heat generated by the magnetic layer 314 due to the alternating magnetic field 356 facilitates annealing the conductive features 310, 334 and the formation of the conductive interconnection 352.

Some of the heat generated by the magnetic layer 314 due to the alternating magnetic field 356 may also spread to other portions of the first and second elements 300, 330, such as the base substrate portion 302. However, the heat is localized around the magnetic layer 314 and does not spread far from the magnetic layer 314 such that portions of the base substrate 302 that are remote from the bonding layer 304 (and therefore remote from the magnetic layer 314) are not significantly heated during the induction heating process. With this arrangement, inductively heating the first and second elements 300, 330 enables localized spike anneals around the conductive feature 310 and generally within the bonding layer 304 without substantially heating the base substrate portion 302. Accordingly, inductively heating the first and second elements 300, 330 of the bonded structure 350 can enable the formation of metal-to-metal direct bonds without significantly heating the remainder of the elements 300, 330 or the bonded structure 350, thus preserving thermal budget. For example, while the conductive feature 310 reaches around 200° C.±25° C. during the induction heating process, the backside of the element 300 opposite the bonding surface 320 can remain significantly cooler, for example between about 50° C. and 180° C., such as less than 150° C.

In some embodiments, the induction heating apparatus 354 is separate from the apparatus(es) used to bond the first dielectric field region 322 to the second dielectric field region 338, including the apparatus used to initially heat the first and second elements 300, 330 to increase the strength of the chemical bond between the first and second dielectric field regions 322, 338. In these embodiments, after the first dielectric field region 322 is bonded to the second dielectric field region 338, the first and second elements 300, 330 are moved from the apparatuses used to strengthen the bond between the first dielectric field region 322 and the second dielectric field region 338 and positioned in the induction heating apparatus 354 before the induction heating process begins. In these embodiments, the induction heating process is performed after the first dielectric field region 322 is bonded to the second dielectric field region 338 and initially heated, such as in an oven. In other embodiments, however, the induction heating apparatus 354 and one or more of the apparatus(es) used to bond the first dielectric field region 322 to the second dielectric field region 338 are adjacent to each other and/or incorporated into the same apparatus, such as in a cluster tool or in the same chamber. In these embodiments, the induction heating process can be performed after the initial heating, or can be performed while the bonded structure 350 is being initially heated to strengthen the bond between the first dielectric field region 322 and the second dielectric field region 338. For example, in some embodiments, the induction heating apparatus 354 and the apparatus used to heat the first and second elements 300, 330 to increase the strength of the chemical bond between the first and second dielectric field regions 322, 338 are incorporated into the same apparatus. In these embodiments, while the thermal heating apparatus heats the dielectric field regions 322, 338 to a temperature of 120° C. or less, such as by radiative, convective or conductive heating means, to increase the strength of the chemical bond between the first and second dielectric field regions 322, 338, the induction heating apparatus 354 can simultaneously locally heat the magnetic layer 314 (and therefore the conductive layer 332) to a temperature of 200° C. or more to form metal-to-metal direct bonds between the first and second conductive features 310, 334.

In the embodiment shown in FIGS. 3A-3D, the conductive feature 310 includes the conductive metal 312, the magnetic layer 314, the barrier layer 316, and the adhesion layer 318, where the barrier layer 316 lines the bottom and sidewalls of the cavity in which the conductive feature 310 is formed, the magnetic layer 314 is formed over the barrier layer 316, the adhesion layer 318 is formed over the magnetic layer 314, and the conductive metal 312 is formed over the adhesion layer 318 and fills the cavity. In other embodiments, however, the conductive feature can have a different structure and/or may not have one or more of the barrier layer and the adhesion layer, as noted above.

FIGS. 4A-4D are schematic side sectional views of elements 400A-400D. The elements 400A-400D may be similar or identical to the element 300 discussed above in many respects. Accordingly, numerals used to identify features of the element 300 are incremented by 100 to identify similar or identical features of the elements 400A-400D. For example, the elements 400A-400D each include a base substrate portion 402 and a bonding layer 404 formed over the base substrate portion 402. The base substrate portions 402 comprise active devices and/or circuitry 406, including BEOL or RDL metallization, and the bonding layer 404 comprises a dielectric layer 408 and a conductive feature 410A-410D formed in a cavity in the dielectric layer 408. Each of the conductive features 410A-410D can comprise a magnetic layer 414A-414D and a conductive metal 412, where the magnetic layer comprises a magnetic material. However, other aspects of the conductive features 410A-410D may be different from the conductive feature 310.

In the embodiment shown in FIG. 4A, the conductive feature 410A comprises a (non-magnetic) conductive metal 412, a magnetic layer 414A, a barrier layer 416, and an adhesion layer 418. Additionally, the magnetic layer 414A is formed from a metallic and electrically conductive magnetic material (e.g., Ni, a Ni—Fe alloy, Co, a Co—Zr alloy, CoZrTa, Permalloy, Superpermalloy, Sm, or Nd) to facilitate electrical communication between the active devices and/or circuitry 406 and the conductive metal 412. However, unlike the conductive feature 310 of FIGS. 3A-3D, the conductive feature 410A is formed by depositing the adhesion layer 418 in a cavity patterned into the dielectric layer 408, depositing the magnetic layer 414A over the adhesion layer 418, depositing the barrier layer 416 over the magnetic layer 414A, and then depositing the conductive metal 412 over the barrier layer 416 to fill the rest of the cavity. With this arrangement, the conductive feature 410A is formed such that adhesion layer 418 lines the bottom and sidewalls of the cavity in which the conductive feature 410A is formed, the magnetic layer 414A is formed over the adhesion layer 418, the barrier layer 416 is formed over the magnetic layer 414A, and the conductive metal 412 is formed over the barrier layer 416 and fills the cavity.

In the embodiment shown in FIG. 4B, the conductive feature 410B comprises the conductive metal 412, the magnetic layer 414B, and a barrier layer 416 but does not include an adhesion layer. Additionally, the magnetic layer 414B is formed from a metallic magnetic material and is formed at the bottom of the cavity but does not line the sidewalls of the conductive metal 412. The conductive feature 410B is formed by depositing the barrier layer 416 in a cavity patterned into the dielectric layer 408, depositing the magnetic layer 414B over a bottom portion of the barrier layer 416, and then depositing the conductive metal 412 over the magnetic layer 414B to fill the rest of the cavity. With this arrangement, the conductive feature 410B is formed such that the barrier layer 416 lines the bottom and sidewalls of the cavity in which the conductive feature 410B is formed, the magnetic layer 414B is at the bottom of the cavity and covers a bottom portion of the barrier layer 416, and the (non-magnetic) conductive metal 412 is formed over the magnetic layer 414B and fills the cavity. When the element 400B is exposed to the alternating magnetic field during the induction heating process, the magnetic layer 414B heats up and the heat generated spreads into the bottom of the conductive metal 412. The conductive metal 412 can have a high thermal conductivity so the heat emitted by the magnetic layer 414B can quickly spread through the conductive metal 412 to cause the conductive metal 412 to expand, bridge any gap with an opposing conductive feature on the opposite element to be bonded, and form a metal-to-metal direct bond.

In the embodiments shown in FIG. 4C, the conductive feature 410C comprises the (non-magnetic) conductive metal 412 and the magnetic layer 414C (which is formed from a metallic material) but does not include an adhesion layer or barrier layer. The conductive feature 410C is formed by depositing the magnetic layer 414C in a cavity patterned into the dielectric layer 408 and then depositing the conductive metal 412 over the magnetic layer 414C to fill the rest of the cavity. With this arrangement, the conductive feature 410C is formed such that the magnetic layer 414C lines the bottom and sidewalls of the cavity in which the conductive feature 410C is formed and the conductive metal 412 is formed over the magnetic layer 414C and fills the cavity.

In the embodiments shown and described in connection with FIG. 3A-4C, the magnetic layers 314, 414A-414C are formed at least at the bottom of the conductive metal 312, 412 between the conductive metal 412 and the active devices and/or circuitry 306, 406. In these embodiments, the magnetic layers 314, 414A-414C are formed from metallic and electrically conductive magnetic materials and electrically couples the conductive metal 312, 412 to the active devices and/or circuitry 306, 406. In other embodiments, however, the magnetic layers may not be formed at the bottom of the of the conductive metal 312, 412. For example, in the embodiment shown in FIG. 4D, the magnetic layer 414D is formed on the sidewalls of the conductive metal 412 and between the conductive metal 412 and the dielectric layer 408 but is not formed at the bottom of the conductive metal 412. In these embodiments, the conductive metal 412 can be formed directly on the active devices and/or circuitry 406 while the magnetic layer 414D lines the sidewalls of the conductive metal 412. In some embodiments, the magnetic layer 414D is formed from a conductive magnetic material (e.g., Ni, a Ni—Fe alloy, Co, a Co—Zr alloy, CoZrTa, Permalloy, superpermalloy, Sm, or Nd). In other embodiments, however, the magnetic layer 414D can be formed from a ceramic magnetic material, such as magnetite (Fe₃O₄) or nickel ferrite.

In the embodiments shown and described in connection with FIGS. 3A-4D, the conductive features include a layer of a magnetic material formed on one or more sides of the conductive metal that fill the cavities. In other embodiments, however, the magnetic material can be incorporated into the conductive metal of the conductive feature.

FIGS. 5A-5C are schematic side sectional views of elements 500A-500C. The elements 500A-500C may be similar or identical to the element 300 discussed above in many respects. Accordingly, numerals used identify features of the element 300 are incremented by 200 to identify similar or identical features of the elements 500A-500C. For example, the elements 500A-500C each include a base substrate portion 502 and a bonding layer 504 formed over the base substrate portion 502. The base substrate portions 502 comprise active devices and/or circuitry 506, including metallization layers, and the bonding layers 504 comprise a dielectric layer 508 and a conductive feature 510A-510C formed in a cavity in the dielectric layer 508.

Each of the conductive features 510A-510C comprise a conductive metal 512 (e.g., Cu), a barrier layer 516, and magnetic particles 526 embedded in the conductive metal 512, where the magnetic particles 526 comprise a magnetic material. In some embodiments, the magnetic particles 526 comprise a magnetic material having a relative magnetic permeability of about 3 or greater. In some embodiments, the magnetic particles 526 comprise a conductive material such as the magnetic layer materials noted above, including Ni and/or Co. In some embodiments, the magnetic particles 526 comprise a ceramic magnetic material. For example, in some embodiments, the magnetic particles 526 comprise magnetite (Fe₃O₄) or nickel ferrite. In some embodiments, some or all of the magnetic particles 526 are nanoparticles. In some embodiments, the magnetic particles 526 can have an average diameter between about 5 nm and 500 nm, or between about 5 nm and 50 nm. In some embodiments, the magnetic particles 526 can take up about 10% +3% of the volume of the cavity in which the conductive features 510A-510C are formed. In other embodiments, however, the magnetic particles 526 can take up a different percentage of the volume of the cavity. For example, in some embodiments, the magnetic particles 526 can take up between 1% and 20% of the volume of the cavity, between 5% and 15% of the volume of the cavity, between 5% and 10% of the volume of the cavity, between 10% and 15% of the volume of the cavity, less than 15% of the volume of the cavity, or a value in a range defined by any of these embodiments. In some embodiments, the percentage of the volume of the cavity that the magnetic particles 526 take up can depend on the composition of one or both of the magnetic particles 526 and the conductive metal 512. In some embodiments, the magnetic particles 526 and conductive metal 512 can be formed using a co-deposition process, such as a co-plating process or a co-sputtering process.

When the elements 500A-500C are inductively heated, the magnetic particles 526 heat up due to the alternating magnetic field. When the elements 500A-500C are being hybrid bonded, as described with respect to FIGS. 2-3D, the heat generated by the magnetic particles 526 can spread to the conductive metal 512, causing it to expand until the surface 524 of the conductive metal 512 contacts the surface of the opposing conductive feature and a metal-to-metal direct bond is formed.

In some embodiments, such as the embodiment shown in FIG. 5A, the magnetic particles 526 are in an upper portion of the conductive metal 512 that is proximal to the surface 524. In other embodiments, however, the magnetic particles 526 are in a different portion of the conductive metal 512. For example, in some embodiments, such as the embodiment shown in FIG. 5B, the magnetic particles 526 are in a lower portion of the conductive metal 512 that is distal to the surface 524. In still other embodiments, such as the embodiment shown in FIG. 5C, the magnetic particles 526 are evenly distributed throughout conductive metal 512 such that the microwave particles 526 are evenly distributed throughout the upper and lower portions of the conductive metal. In general, the magnetic particles 526 can be formed in any suitable position within the conductive metal 512.

### Conductive Features Having Microwave Susceptible Materials

An alternative way of facilitating the annealing process is to incorporate microwave susceptible materials into the bonding layer. When a microwave susceptible material is exposed to electromagnetic radiation, the electromagnetic radiation excites the atoms and/or molecules of the material, which can cause the material to heat up locally. However, the amount that the electromagnetic radiation excites a given material depends on the wavelength/frequency of the electromagnetic radiation and the atomic and molecular structure of the material. For example, microwave radiation tends to be absorbed by polar molecules (e.g., molecules having a dipole moment of about 2 debye (D) or greater) more than by non-polar molecules, so materials having polar molecules tend to be heated by microwave radiation more effectively than materials with non-polar molecules. Additionally, conductive materials, such as copper, tend to reflect most of the microwave radiation instead of absorbing it and are therefore not significantly heated by microwave radiation. Accordingly, in some embodiments, the bonding layer of the elements can include one or more microwave susceptible materials that are dielectrics and that comprise polar molecules that rapidly heat up when exposed to microwave radiation. The heat generated within the microwave susceptible material can spread by conduction to adjacent features, resulting in localized heating of those features even if those features are not directly heated by the microwave radiation. Accordingly, a microwave heating system can be used to heat up conductive features that include a microwave susceptible material and/or that are adjacent (e.g., surrounded by) a microwave susceptible material, which can cause the conductive feature to expand and contact the opposing conductive feature during the annealing process.

The frequency of the radiation also affects how much the radiation penetrates into the material. For example, higher frequency radiation, such as infrared and visible light, tends to be absorbed at the surface of the material while lower frequency radiation, such as microwaves, penetrate deeper into certain types of material before being absorbed. Accordingly, the microwave susceptible material can be incorporated into the bonding layer below the bonding surface. However, the absorption of the microwave radiation by the microwave susceptible material reduces the amount of microwave radiation that penetrates below the bonding layer. With this arrangement, a microwave heating system can be used to anneal a bonded structure (comprising elements being bonded together to form a metal-to-metal direct bond) without exceeding the thermal budgets of the elements because the microwave heating system may allow for rapid heating the conductive features being bonded without (or without significantly) heating materials of a base substrate portion below the bonding layer.

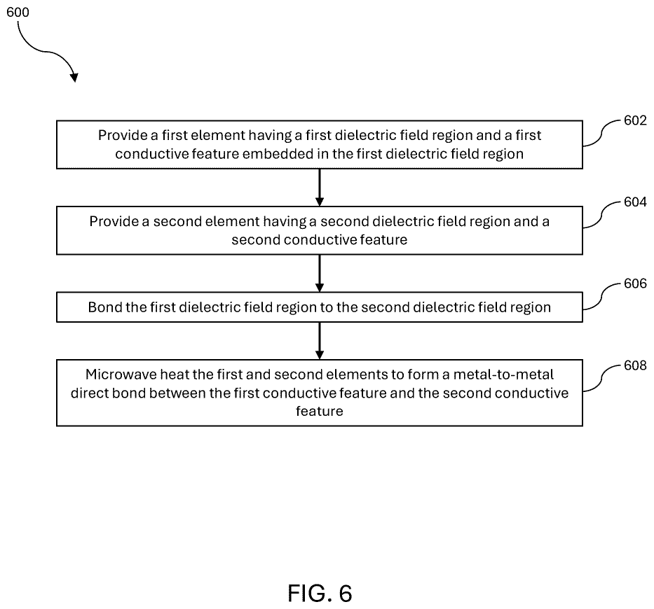

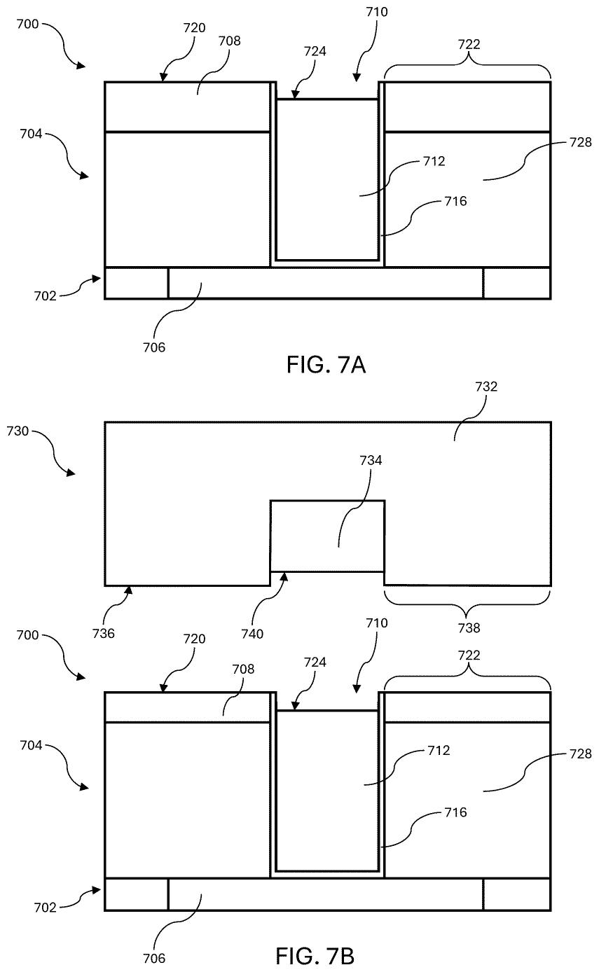

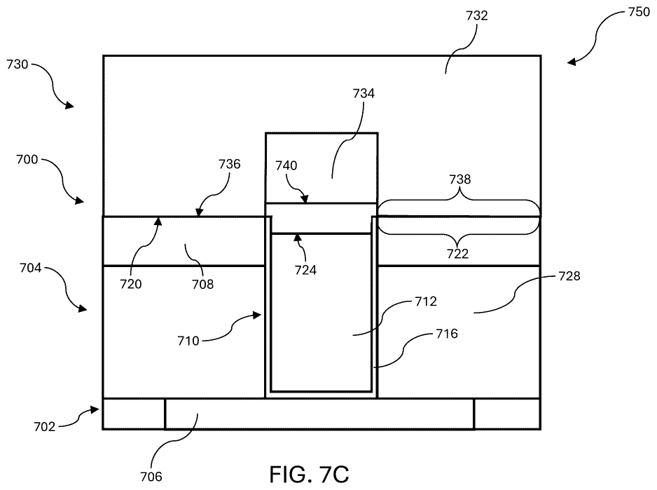

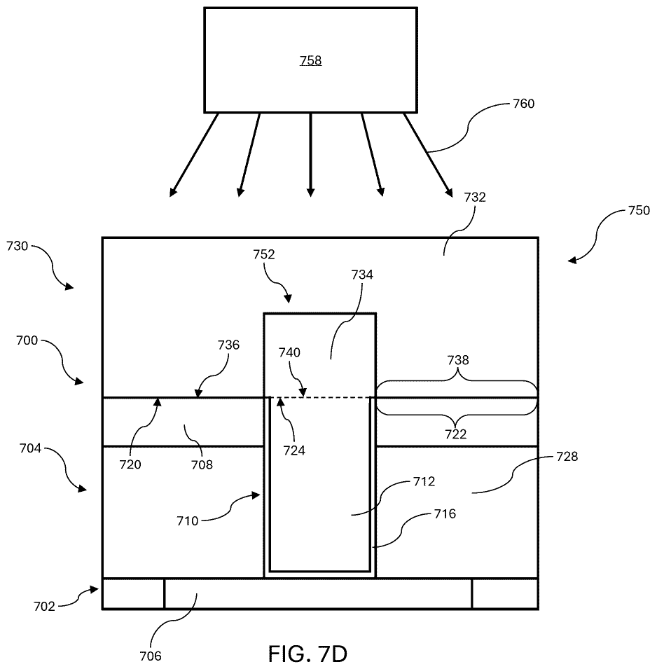

FIG. 6 is a flowchart illustrating a process 600 for forming a bonded microelectronic structure, where the bonded structure includes an element having a bonding layer that includes a microwave susceptible material. FIGS. 7A-7D are schematic side sectional views of microelectronic elements at various blocks of the process 600 shown in FIG. 6.

Referring to FIGS. 6 and 7A, at block 602, an element 700 is provided. The element 700 comprises a base substrate portion 702 and a bonding layer 704 formed over the base substrate portion 702. The base substrate portion 702 comprises active devices and/or circuitry 706 (including interconnect or metallization layers) and the bonding layer 704 comprises a dielectric layer 708, a conductive feature 710, and a microwave susceptible layer 728, where the dielectric layer 708 comprises a dielectric material that is relatively transparent to microwave radiation and the microwave susceptible layer 728 comprises a dielectric material that absorbs microwave radiation more than the dielectric layer 708. The conductive feature 710 comprises a conductive metal 712 and a barrier layer 716. In some embodiments, the conductive metal 712 comprises copper. In other elements, the conductive metal 712 comprises a different element, such as nickel or aluminum. In some embodiments, the conductive metal 712 comprises an alloy of one or more of copper, gold, nickel, and/or aluminum. The bonding layer 704 has a bonding surface 720 that includes a dielectric field region 722 and a surface 724 of the conductive metal 712 of the conductive feature 710, where the dielectric field region 722 is at least partially formed by the dielectric layer 708. In some embodiments, the surface 724 of the conductive metal 712 is recessed below the dielectric field region 722.

The conductive feature 710 can be formed, for example, using a damascene process that includes forming the microwave susceptible layer 728 and the dielectric layer 708 on the base substrate portion 702, patterning the microwave susceptible layer 728 and the dielectric layer 708 to form a cavity, forming the barrier layer 716 in the cavity to line the bottom surface and sidewalls of the cavity and then forming the conductive metal 712 over the barrier layer 716 to at least partially fill the cavity. In some embodiments, one or both of the barrier layer 716 and the conductive metal 712 are formed using a deposition process (e.g., a PVD deposition process) or a plating process. The barrier layer 716 is designed to prevent the conductive metal 712 from diffusing into the microwave susceptible layer 728 and the dielectric layer 708. In some arrangements, the barrier layer 716 can comprise titanium (Ti) or tantalum (Ta). For example, the barrier layer 716 can comprise Ti metal and/or TiN or Ta metal and/or TaN. In the illustrated embodiment, the conductive feature 710 does not include an adhesion layer. In other embodiments, the conductive feature 710 can include an adhesion layer.

The microwave susceptible layer 728 comprises a dielectric material having polar molecules that readily and rapidly heat up when exposed to microwave radiation. As discussed in greater detail elsewhere in the specification, the element 700 can be exposed to a microwave heating system that is configured to generate microwave radiation (e.g., electromagnetic radiation with a wavelength between 1 mm and 1 m). When a microwave susceptible layer 728 is exposed to microwave radiation, the microwave radiation excites the polar molecules within the microwave susceptible material, causing them to oscillate back and forth, resulting in an increase in the temperature of the microwave susceptible layer 728. Other materials, such as the non-polar dielectric material that forms the dielectric layer 708 and the conductive metal 712, do not directly heat up when exposed to microwave radiation. For example, in some embodiments, the dielectric layer 708 comprises a non-polar dielectric material, such as silicon oxide (SiO), silicon nitride (SiN) or silicon oxynitride (SiON), and is suitable for direct bonding. Accordingly, when the element 700 is exposed to the microwave heating system, microwave susceptible layer 728 can heat up while other portions of the element 700 (e.g., conductive metal 712, dielectric layer 708, base substrate portion 702) are not directly heated by the microwave heating system. However, the heat generated by the microwave susceptible layer 728 during the microwave heating process can spread by conduction to adjacent or surrounding structures. Conventional dielectrics, such as silicon oxide, in the structure inhibit heat conduction. With this arrangement, exposing the element 700 to a microwave heating system can allow for the selective and localized heating of the conductive feature 710 during annealing process without heating (or without substantially heating) other portions of the element 700 that are more sensitive to elevated temperatures also being heated.

In some embodiments, the microwave susceptible layer 728 comprises a dielectric material that includes polar molecules having a dipole moment of 2 D or greater. For example, in some embodiments, the microwave susceptible layer 728 comprises a dielectric material that includes polar molecules having a dipole moment between about 2D and about 15 D, about 2 D and about 5 D, between about 5 D and about 10 D, between about 10 D and 15 D, of about 2 D or greater, about 5 D or greater, about 10 D or greater, or a value in a range defined by any of these values. In some embodiments, the microwave susceptible layer 728 comprises silicon carbide (SiC), silicon carbonitride (SiCN), aluminum oxide (Al₂O₃), aluminum nitride (AIN), yttria stabilized zirconia (YSZ), zirconium oxide (ZrO₂), boron nitride (BN), etc. In some embodiments, the microwave susceptible layer 728 has a thickness of about 100 nm to 3000 nm. In some embodiments, including the illustrated embodiment, the thickness of the microwave susceptible layer 728 is greater than a thickness of the dielectric layer 708.

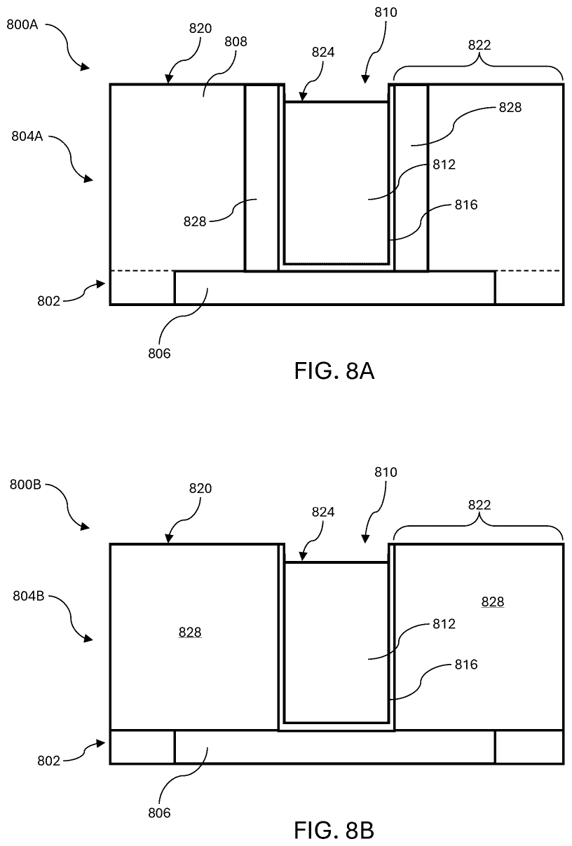

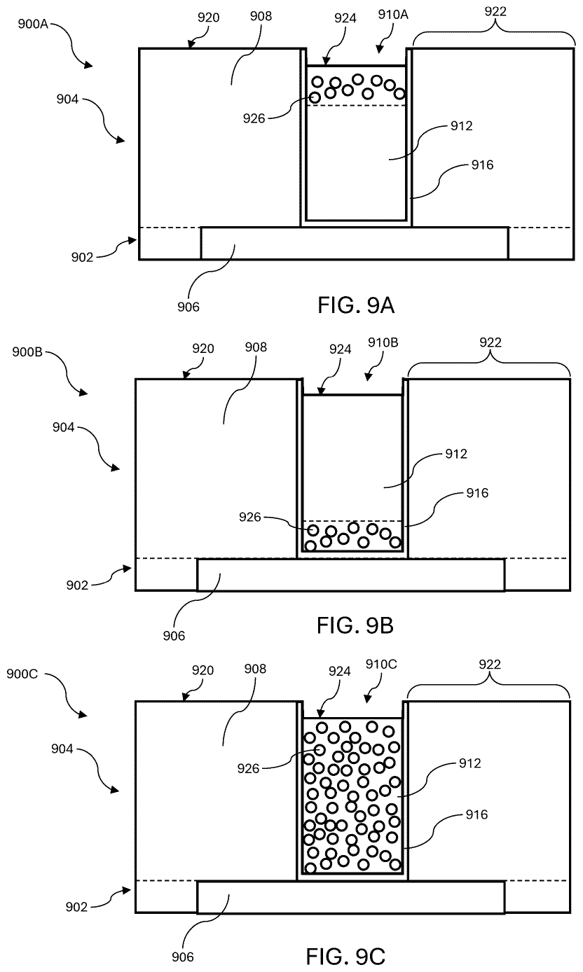

As shown in FIG. 7B, at block 604, a second element 730 is provided. The second element 730 comprises a dielectric layer 732 and a conductive feature 734 and has a bonding surface 736 that includes a dielectric field region 738 and a surface 740 of the conductive feature 734. In some embodiments, the second element 730 has a structure that is generally similar to the structure of element 700. For example, in some embodiments, the second element 730 includes a bonding layer that includes a dielectric layer and a microwave susceptible layer that is adjacent (e.g., at least partially surrounds) the conductive feature 734, where the dielectric layer 732 includes a dielectric material that is relative transparent to microwave radiation while the microwave susceptible layer includes a dielectric material that absorbs microwave radiation more than the material of the dielectric layer 732. The second element can also include active devices and/or circuitry. In other embodiments, however, the second element 730 can have a structure that is different from the structure of the element 700. For example, in some embodiments, the second element 730 may not include a bonding layer that includes a microwave susceptible material. In some embodiments, the second element 730 can have a bonding layer that includes a microwave susceptible material but that has a different structure than the bonding layer 704. In some embodiments, the bonding layer 704 can have a structure that is generally similar to that of one of the bonding layers 804A, 804B shown in FIGS. 8A and 8B or bonding layers 904A-904C shown in FIGS. 9A-9C. In some embodiments, including the illustrated embodiment, the surface 740 of the conductive feature 734 is recessed below the dielectric field region 738. In other embodiments, however, the surface 740 of the conductive feature 734 can be coplanar with the dielectric field region 738. In some embodiments, at least a portion of the surface 740 can protrude past the dielectric field region 738.

As shown in FIG. 7C, at block 606, the dielectric field region 722 of the element 700 is bonded to the dielectric field region 738 of the element 730 to form a bonded structure 750. In some embodiments, the dielectric field region 722 is directly bonded to the dielectric field region 738 with a dielectric-to-dielectric direct bond and without an adhesive. In some embodiments, the dielectric field region 722 is directly bonded to the dielectric field region 738 by bringing the elements 700, 730 together until the dielectric field regions 722, 738 contact each other. In some embodiments, strong chemical bonds between the dielectric field regions 722, 738 can occur spontaneously upon the dielectric field regions being brought into contact with each other, even at room temperature. In some embodiments, the chemical bonds can form without applying a voltage or external pressure or force beyond that used to initiate contact between the two dielectric field regions 722, 738. In some embodiments, bonding the dielectric field region 722 to the dielectric field region 738 comprises planarizing and chemically preparing (e.g., activating and/or terminating) one or both of the dielectric field regions 722, 738.

In some embodiments, bonding the dielectric field region 722 to the dielectric field region 738 does not include heating the first and second elements 700, 730. In other embodiments, however, bonding the dielectric field regions 722, 738 together comprises heating the elements 700, 730 after contacting the dielectric field regions 722, 738 together to increase the strength of the chemical bonds between the dielectric field regions 722, 738. In these embodiments, the first and second elements 700, 730 can be heated to a temperature that is high enough to increase the strength of the chemical bonds between the dielectric field regions 722, 738 but that is below the temperature needed to cause the conductive features 710, 734 to bond together. For example, in some embodiments, bonding the dielectric field region 722 to the dielectric field region 738 comprises heating the dielectric field regions 722, 738 of the elements 700, 730 to a temperature of 120° C. or less. Accordingly, after heating the elements 700, 730 during the process of bonding the dielectric field region 722 to the dielectric field region 738, the conductive features 710, 734 are not bonded to each other. Additionally, in embodiments where one or both of the surfaces 724, 740 conductive features 710, 734 are recessed below the respective dielectric field regions 722, 738 prior to bonding the dielectric field regions 722, 738, the elements 700, 730 are heated to a temperature that is too low to cause the conductive features 710, 734 to expand and the surfaces 724, 740 to contact each other. Accordingly, in these embodiments, after heating the elements 700, 730 during the process of bonding the dielectric field region 722 to the dielectric field region 738, the surfaces 724, 740 can be spaced apart from each other by a gap. In some embodiments, the elements 700, 730 are heated using a radiative, a convection, and/or a conductive heating process, such as by use of a standard anneal oven. Typically such anneals result in the relatively uniform heating of the entire bonded structure 750.

As shown in FIG. 7D, at block 608, the bonded structure 750, including first and second elements 700, 730, is subjected to microwave energy to form a metal-to-metal direct bond between first conductive feature 710 and the second conductive feature 734 and to form a conductive interconnection 752 that includes the first and second conductive features 710, 734. The bonded structure 750 can be microwave heated using a microwave heating apparatus 758, which is configured to generate microwave radiation 760 and direct the microwave radiation 760 towards the bonded structure 750. In the illustrated embodiment, the microwave heating apparatus 758 is positioned over the bonded structure 750 such that the microwave radiation 760 penetrates through surrounding materials of the first and second elements 700, 730 but is absorbed by the microwave susceptible layer 728.

In some embodiments, microwave heating the first and second elements 700, 730 comprises placing the bonded structure 750 (including the first and second elements 700, 730) into a microwave heating apparatus 758 to generate microwave radiation 760 having a wavelength between about 1 mm and about 1 m and a frequency between about 300 MHz and about 300 GHz. In some embodiments, the microwave radiation 760 has a consistent wavelength and frequency for the duration of the microwave heating process. In other embodiments, however, the microwave radiation 760 can change frequency and wavelength during the microwave heating process. For example, in some embodiments, the microwave radiation 760 is variable frequency microwave (VFM) radiation that changes frequency throughout the microwave heating process. With this arrangement, the microwave radiation 760 does not form standing waves within the chamber where the microwave heating process is being performed, which reduces or even eliminates sparking from the metal parts of the bonded structure. Accordingly, microwave heating the bonded structure using VFM radiation can avoid causing the metal parts from sparking during the microwave heating process.

The amount of energy that a microwave susceptible material can absorb from a given photon of microwave radiation can depend on frequency of the photon and the microwave absorption properties of the microwave susceptible material. Specifically, the energy of an individual photon is proportional the frequency of the photon (per Planck's equation), so a photon with a higher frequency will have more energy for the microwave susceptible material to absorb than a photon with a lower frequency. However, the efficiency of a microwave susceptible material at absorbing energy from a given photon can vary with the frequency and may not be proportional to the frequency of the photon. Accordingly, although the microwave susceptible material can absorb energy from photons with frequencies across the entire microwave radiation spectrum (e.g., frequencies from about 300 MHz to about 300 GHz), the amount of energy that a microwave susceptible material absorbs can vary with the frequency of the microwave radiation. Absorption can be proportional to ϵᵣ″ (f)*f, where ϵᵣ″ is imaginary part of relative permittivity of material that has its own dependence upon frequency, and f is the frequency of the applied energy. The peak microwave absorption frequency of a given material may be less than a maximum frequency of the microwave radiation spectrum (e.g., a frequency less than 300 GHz). For example, silicon carbide and silicon carbonitride have peak microwave frequency absorption frequencies in the range of about 2-18 GHz, depending upon the stoichiometry of these materials. In some embodiments, including embodiments where the microwave radiation 760 is VFM radiation, the microwave radiation 760 can be tuned to the peak microwave absorption frequency of the microwave susceptible material. In some embodiments, the microwave radiation 760 can have a frequency within ±50% of the peak microwave absorption frequency of the microwave susceptible material, and can be scanned across frequencies with this range.

As the microwave radiation 760 penetrates through various materials of the first and second elements 700, 730, the microwave radiation excites polar molecules of first and second elements 700, 730, causing such materials to heat up. As noted above, the amount that a given molecule is heated by the microwave radiation tends to depend on the polarity of the molecule, where polar molecules tend to rapidly heat up in the presence of an alternating electric field while non-polar molecules do not directly heat up when exposed to an alternating electrical field. Additionally, metals tend to reflect electromagnetic radiation instead of absorbing it, and therefore are not significantly heated by microwave radiation. Accordingly, when the microwave radiation 760 penetrates through materials of the first and second elements 700, 730, the microwave susceptible layer 728, which can be formed from a polar dielectric material, can rapidly heat while other portions of the first and second elements 700, 730, such as the dielectric layer 708 and the conductive features 710, 734, are not directly heated by the microwave radiation 760.

In some embodiments, microwave heating the bonded structure 750 causes the microwave susceptible layer 728 to locally heat up to a temperature of between about 400° C. and about 500° C. or more. In other embodiments, however, microwave heating the bonded structure 750 causes the microwave susceptible layer 728 to be heated to a different temperature. For example, in some embodiments, microwave heating the bonded structure 750 causes the microwave susceptible layer 728 to be heated to a temperature between 200° C. and 700° C., between 300° C. and 600° C., between 400° C. and 500° C., between 350° C. and 550° C., between 400° C. and 450° C., between 450° C. and 500° C., between 350° C. and 450° C., between 450° C. and 550° C., a temperature greater than 700° C., or a value in a range defined by any of these ranges. In some embodiments, microwave heating the bonded structure 750 comprises microwave heating the first and second elements 700, 730 for a time between about 1 second and about 1800 seconds.

The heat generated by the microwave susceptible layer 728 due to the microwave radiation 760 spreads by conduction to the adjacent barrier layer 716 and conductive metal 712. Accordingly, while microwave heating the first and second elements 700, 730 can cause the microwave susceptible layer 728 to rapidly heat up, the conductive metal 712 has high thermal conductivity and conducts the heat away from the microwave susceptible layer 728, causing the conductive metal 712 to heat up. For example, in some embodiments, microwave heating the bonded structure 750 can cause the conductive feature 710 (including the conductive metal 712) to heat up to a temperature between about 200° C. and about 250° C. In other embodiments, however, microwave heating the bonded structure 750 can cause the conductive feature 710 to heat up to a different temperature. For example, in some embodiments, microwave heating the bonded structure 750 can cause the conductive feature 710 generally, and the conductive metal 712 in particular, to heat up to a temperature between about 150° C. and about 300° C., between about 150° C. and about 200° C., between about 200° C. and about 250° C., between about 250° C. and about 300° C., a temperature greater than about 200° C., or a value in a range defined by any of these values. In some embodiments, microwave heating the bonded structure 750 can cause the conductive feature 710 to heat up without melting the conductive metal 712 or the microwave susceptible layer 728.

As the conductive metal 712 heats, it expands toward the second conductive feature 734 until the surface 724 of the conductive metal 712 contacts the surface 740 of the second conductive feature 734 and a metal-to-metal direct bond is formed between the conductive features 710, 734. Accordingly, the heat generated by the microwave susceptible layer 728 due to the microwave radiation 760 facilitates annealing the conductive features 710, 734 and the formation of the conductive interconnection 752.

Some of the heat generated by the microwave susceptible layer 728 due to the microwave radiation 760 may also spread to other portions of the first and second elements 700, 730, such as the base substrate portion 702. However, the heat is localized around the microwave susceptible layer 728 and may not spread far from the microwave susceptible layer 728 such that portions of the base substrate 702 that are remote from the bonding layer 704 (and therefore further from the microwave susceptible layer 728) are not significantly heated during the microwave heating process. With this arrangement, microwave heating the bonded structure 750 enables localized spike anneals around the conductive feature 710 and generally within the bonding layer 704 significantly less heating the base substrate portion 702. Accordingly, microwave heating the first and second elements 700, 730 can enable the formation of metal-to-metal direct bonds without significantly heating the remainder of the elements 700, 730 of the bonded structure 750, thus preserving thermal budgets. For example, while the conductive feature 710 reaches around 200° C.±25° C. during the microwave heating process, the backside of the element 700 opposite the bonding surface 720 can remain significantly cooler, for example between about 50° C. and 180° C., such as less than 150° C.

In some embodiments, the microwave heating apparatus 758 is separate from the apparatus(es) used to bond the first dielectric field region 722 to the second dielectric field region 738, including the apparatus used to initially heat the first and second elements 700, 730 to increase the strength of the chemical bond between the first and second dielectric field regions 722, 738. In these embodiments, after the first dielectric field region 722 is bonded to the second dielectric field region 738, the first and second elements 700, 730 are moved from the apparatuses used to strengthen the bond between the first dielectric field region 722 and the second dielectric field region 738 and positioned in the microwave heating apparatus 758 before the microwave heating process begins. In these embodiments, the microwave heating process is performed after the first dielectric field region 722 is bonded to the second dielectric field region 738 and initially heated, such as in an oven. In other embodiments, however, the microwave heating apparatus 7758 and one or more of the apparatus(es) used to bond the first dielectric field region 722 to the second dielectric field region 738 are adjacent to each other and/or incorporated into the same apparatus, such as in a cluster tool or in the same chamber. In these embodiments, the microwave heating process can be performed after the initial heating or can be performed while the bonded structure 750 is being initially heated to strengthen the bond between the first dielectric field region 722 and the second dielectric field region 738. For example, in some embodiments, the microwave heating apparatus 758 and the apparatus used to heat the first and second elements 700, 730 to increase the strength of the chemical bond between the first and second dielectric field regions 722, 738 are incorporated into the same apparatus. In these embodiments, while the thermal heating apparatus heats the dielectric field regions 722, 738 to a temperature of 120° C. or less, such as by radiative, convective or conductive heating means, to increase the strength of the chemical bond between the first and second dielectric field regions 722, 738, the microwave heating apparatus 758 can simultaneously heat the microwave susceptible layer 728 (and therefore the conductive feature 710) to a temperature of 200° C. or more to form metal-to-metal direct bonds between the first and second conductive features 710, 734.

In the embodiment shown in FIGS. 7A-7D, the bonding layer 704 is formed such that the microwave susceptible layer 728 is formed below the dielectric layer 708 and is not exposed at the bonding surface 720 and does not form portion of the dielectric field region 722. In other embodiments, however, the bonding layer can have a different structure and/or may not include the separate dielectric layer 708.

FIGS. 8A and 8B are schematic side sectional views of elements 800A and 800B. The elements 800A and 800B may be similar or identical to the element 700 discussed above in many respects. Accordingly, numerals used to identify features of the element 700 are incremented by 100 to identify similar or identical features of the elements 800A and 800B. For example, the elements 800A, 800B each include a base substrate portion 802 and a bonding layer 804A, 804B formed over the base substrate portion 802. The base substrate portions 802 comprise active devices and/or circuitry 806 (which may include metallization layers) and the bonding layers 804A, 804B each include a conductive feature 810 that is formed from a conductive metal 812 and that includes barrier layer 816. Additionally, each of the bonding layers 804A, 804B can include a microwave susceptible layer 828. However, other aspects of the bonding layers 804A, 804B can be different from the bonding layer 704.

In the embodiment shown in FIG. 8A, the bonding layer 804A comprises the dielectric layer 808 and the microwave susceptible layer 828. However, unlike the bonding layer 704 of FIGS. 7A-7D, the bonding layer 804A is formed such that the microwave susceptible layer 828 surrounds the conductive feature 810 and extends from the base substrate portion 802 to the bonding surface 820. With this arrangement, the microwave susceptible layer 828 is exposed at the bonding surface 820 and the dielectric field region 822 includes exposed portions of the microwave susceptible layer 828 and the dielectric layer 808. Suitable materials for the microwave susceptible layer 828 and the dielectric layer 808 can be as described for the microwave susceptible layer 728 and the dielectric layer 708, respectively, of FIGS. 7A-7D.

In the embodiment shown in FIG. 8B, the bonding layer 804B comprises the microwave susceptible layer 828 but does not include a separate dielectric layer. In these embodiments, the dielectric field region 822 includes the microwave susceptible layer 828 but does not include another dielectric material. Desirably, the microwave susceptible layer 828 comprises a polar material, but also serves as dielectric suitable for direct bonding. Non-limiting examples include SiC, SiCN, Al₂O₃, AIN, YSZ, ZrO₂, BN.

In the embodiments shown and described in connection with FIGS. 7A-8B, the bonding layers include a microwave susceptible material formed around the conductive features such that the conductive features are at least partially surrounded by the microwave susceptible material. In other embodiments, the microwave susceptible material can be incorporated into the conductive feature.

FIGS. 9A-9C are schematic side sectional views of elements 900A-900C. The elements 900A-900C may be similar or identical to the element 700 discussed above in many respects. Accordingly, numerals used identify features of the element 700 are incremented by 200 to identify similar or identical features of the elements 900A-900C. For example, the elements 900A-900C each include a base substrate portion 902 and a bonding layer 904 formed over the base substrate portion 902. The base substrate portions 902 comprise active devices and/or circuitry 906, including metallization layers, and the bonding layers 904 comprise a dielectric layer 908 and a conductive feature 910A-910C formed in a cavity in the dielectric layer 908.

Each of the conductive features 910A-910C comprises a conductive metal 912 (e.g., Cu), a barrier layer 916, and microwave susceptible particles 926 embedded in the conductive metal 912, where the microwave susceptible particles 926 comprise a microwave susceptible material. In some embodiments, the microwave susceptible particles 926 comprise a dielectric material that includes polar molecules having a dipole moment greater than about 2 D, such as a dipole moment between about 2D and about 15 D. For example, in some embodiments, the microwave susceptible particles 926 comprise SiC, SiCN, Al₂O₃, ZrO₂, BN, etc. In some embodiments, some or all of the microwave susceptible particles 926 are nanoparticles. In some embodiments, the microwave susceptible particles 926 have an average diameter between about 5 nm and 500 nm, or between about 5 nm and 50 nm. In some embodiments, the microwave susceptible particles 926 can take up about 10%±3% of the volume of the cavity in which the conductive features 910A-910C are formed. In other embodiments, however, the microwave susceptible particles 926 can take up a different percentage of the volume of the cavity. For example, in some embodiments, the microwave susceptible particles 926 can take up between 1% and 20% of the volume of the cavity, between 5% and 15% of the volume of the cavity, between 5% and 10% of the volume of the cavity, between 10% and 15% of the volume of the cavity, less than 15% of the volume of the cavity, or a value in a range defined by any of the foregoing values. In some embodiments, the percentage of the volume of the cavity that the microwave susceptible particles 926 take up can depend on the composition of one or both of the microwave susceptible particles 926 and the conductive metal 912. In some embodiments, the microwave susceptible particles 926 and conductive metal 912 can be formed using a co-deposition process, such as a co-plating process or a co-sputtering process.

When a bonded structure that includes one of the elements 900A-900C is microwave heated, the microwave susceptible particles 926 heat up due to the microwave radiation. The heat generated by the microwave susceptible particles 926 can spread by conduction to the conductive metal 912, causing it to expand until the surface 924 of the conductive metal 912 contacts the surface of the opposing conductive feature and a metal-to-metal direct bond is formed.

In some embodiments, such as the embodiment shown in FIG. 9A, the microwave susceptible particles 926 are in an upper portion of the conductive metal 912 that is proximal to the surface 924. In other embodiments, however, the microwave susceptible particles 926 are in a different portion of the conductive metal 912. For example, in some embodiments, such as the embodiment shown in FIG. 9B, the microwave susceptible particles 926 are in a lower portion of the conductive metal 912 that is distal to the surface 924. In still other embodiments, such as the embodiment shown in FIG. 9C, the microwave susceptible particles 926 are evenly distributed throughout conductive metal 912 such that the microwave susceptible particles 926 are evenly distributed throughout the upper and lower portions of the conductive metal. In general, the microwave susceptible particles 926 can be formed in any suitable position within the conductive metal 912.

### Additional Examples

In one aspect, a method is provided for forming a bonded structure. The method includes providing a first element having a first dielectric field region and a first conductive feature embedded in the first dielectric field region. The method also includes providing a second element that has a second dielectric field region and a second conductive feature. The first dielectric field region is bonded to the second dielectric field region. Inductive energy is applied to the first element and/or second element to form a direct bond between the first conductive feature and the second conductive feature.

In some embodiments, the first conductive feature includes a conductive material and a magnetic material, and applying inductive energy uses an induction heating system to heat the magnetic material. Using the induction heating system can direct an alternating magnetic field toward the first and second elements. The magnetic material can have a relative magnetic permeability of about 3 or greater, about 10 or greater, about 50 or greater, or about 100 or greater. Using the induction heating system can heat the magnetic material without melting the conductive material or the magnetic material. The magnetic material can be a first magnetic material, and the second conductive feature can include a second magnetic material. Providing the first element can include forming the first conductive feature in a cavity in a dielectric material of the first dielectric field region. In some cases, forming the first conductive feature can include co-depositing the conductive material and the magnetic material, such as by co-plating. In other cases, forming the first conductive feature can include depositing the conductive material in the cavity after depositing the magnetic material in the dielectric material.

In some embodiments, bonding the first dielectric field region to the second dielectric field region includes initially heating the first and second elements to form a dielectric-to-dielectric direct bond between the first and second dielectric field regions, and initially heating is conducted before applying inductive energy. In some cases, initially heating the first and second elements can heat the first and second elements to a temperature of about 120° C. or less. The temperature comprises can be a first temperature, where applying inductive energy to the first and second elements includes inductively heating the first conductive feature to a second temperature of about 200° C. or greater. A backside of the first element can be at a third temperature while the first conductive feature is at the second temperature, and wherein the third temperature is about 150° C. or less.

In some embodiments, applying inductive energy causes the first conductive feature to expand and contact the second conductive feature.

In some embodiments, applying inductive energy includes inductively heating the first conductive feature after bonding the first dielectric field region to the second dielectric field region.

In some embodiments, applying inductive energy applying inductive energy is conducted while bonding the first and second dielectric field regions.

In another aspect, a microelectronic structure is provided. The microelectronic structure includes a dielectric field region at a hybrid bonding surface of the microelectronic structure. A conductive feature is embedded in the dielectric field region and at the hybrid bonding surface. The conductive feature includes a conductive material and a magnetic material.

In some embodiments, the conductive material includes copper.

In some embodiments, the magnetic material has a relative magnetic permeability of about 3 or greater, about 10 or greater, about 50 or greater, or about 100 or greater.

In some embodiments, an upper surface of the conductive feature is recessed below a surface of the dielectric field region.

In some embodiments, the dielectric field region includes a dielectric material and the conductive feature is formed in a cavity in the dielectric material. In some cases, the magnetic material at least partially lines the cavity. At least a portion of the magnetic material can be between the conductive material and the dielectric material. The magnetic material can include a material selected from the group consisting of nickel, a nickel-iron alloy, cobalt, a cobalt-zirconium alloy, a cobalt, zirconium, and tantalate alloy, Permalloy, Superpermalloy, samarium, and neodymium.

In some embodiments, the magnetic material includes magnetic particles embedded within the conductive material. The magnetic particles can be magnetic nanoparticles. The magnetic particles can include ceramic material. The ceramic material can include magnetite (Fe₃O₄) and/or nickel ferrite. In some cases, the conductive feature has an upper portion that is proximal to the hybrid bonding surface and a lower portion that is distal to the hybrid bonding surface, and the magnetic particles are distributed between the upper and lower portions. In other cases, the conductive feature has an upper portion that is proximal to the hybrid bonding surface and a lower portion that is distal to the hybrid bonding surface, and the magnetic particles are in the upper portion but not in the lower portion. In still other cases, the conductive feature has an upper portion that is proximal to the hybrid bonding surface and a lower portion that is distal to the hybrid bonding surface, and the magnetic particles are positioned in the lower portion but not in the upper portion.

In some embodiments, the dielectric field region is a first dielectric field region and the conductive feature is a first conductive feature. The structure also includes a first element that having the first dielectric field region and the first conductive feature, and a second element hybrid bonded to the first element. The second element includes a second dielectric field region and a second conductive feature, where the first dielectric field region is directly bonded to the second dielectric field region, and the first conductive feature is directly bonded to the second conductive feature.

In accordance with another aspect, a method is provided for forming a bonded structure. The method includes providing a first element having a first dielectric field region and a first conductive feature embedded in the first dielectric field region. The method also includes providing a second element having a second dielectric field region and a second conductive feature. The first dielectric field region is bonded to the second dielectric field region. Microwave energy is applied to the first element and/or second element to form a direct bond between the first conductive feature and the second conductive feature.

In some embodiments, variable frequency microwave radiation is applied. In some cases, the first element includes a microwave susceptible material having a peak microwave absorption frequency, and the variable frequency microwave radiation is within ±50% of the peak microwave absorption frequency.

In some embodiments, bonding the first dielectric field region to the second dielectric field region includes initially heating the first and second elements to form a dielectric-to-dielectric direct bond between the first and second dielectric field regions, and initially heating is conducted prior to applying microwave energy. In some cases, initially heating heats the first and second elements to a temperature of about 120° C. or less. The temperature can be a first temperature, and applying microwave energy to the first and second elements can microwave heat the first conductive feature to a second temperature of about 200° C. or greater. A backside of the first element can be at a third temperature while the first conductive feature is at the second temperature, where the third temperature can be about 150° C. or less.

In some embodiments, applying microwave energy causes the first conductive feature to expand and contact the second conductive feature.

In some embodiments, applying microwave energy microwave heats at least the first conductive feature after bonding the first dielectric field region to the second dielectric field region.

In some embodiments, applying microwave energy microwave heats at least the first conductive feature while bonding the first dielectric field region to the second dielectric field region.

In some embodiments, the first element includes a bonding layer that in turn includes the first conductive feature and the first dielectric field region. The bonding layer includes a microwave susceptible material. In some cases, the microwave susceptible material can include a polar molecule having a dipole moment of about 2 D or greater, about 5 D or greater, or about 10 D or greater. Microwave heating the first and second elements can microwave heat the microwave susceptible material to indirectly heat the first conductive feature.

In accordance with another aspect, a microelectronic structure is provided. The structure includes a base substrate portion and a bonding layer formed over the base substrate portion. The bonding layer has a hybrid bonding surface and includes a first dielectric material at the hybrid bonding surface; a second dielectric material that includes a microwave susceptible material; and a conductive feature at the hybrid bonding surface.

In some embodiments, the microwave susceptible material includes a material selected from the group consisting of silicon carbide, silicon carbonitride, aluminum oxide, aluminum nitride, yttria stabilized zirconia, zirconium oxide, and boron nitride.

In some embodiments, the microwave susceptible material includes a polar molecule having a dipole moment of about 2 D or greater, about 5 D or greater, or about 10 D or greater.

In some embodiments, the hybrid bonding surface includes a dielectric field region that includes the first dielectric material, and the conductive feature is embedded in the dielectric field region. In some cases, the dielectric field region also includes the microwave-susceptible material. In other cases, the dielectric field region does not include the microwave susceptible material. In some cases, the dielectric field region is a first dielectric field region and the conductive feature is a first conductive feature. The microelectronic structure additionally includes a first element that in turn includes the bonding layer and the base substrate portion, and a second element hybrid bonded to the first element. The second element includes a second dielectric field region and a second conductive feature. The first dielectric field region is directly bonded to the second dielectric field region, and the first conductive feature is directly bonded to the second conductive feature.

In some embodiments, the microwave susceptible material includes microwave susceptible particles embedded in a conductive metal of the conductive feature. In some cases, the conductive metal includes copper.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

While certain embodiments have been described, these embodiments have been presented by way of example only, and are not intended to limit the scope of the disclosure. For example, while illustrated embodiments include preparation for direct hybrid bonding, the skilled artisan will appreciate that the techniques taught herein can be useful for direct metal bonding even in the absence of direct dielectric bonding. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. It is also contemplated that various combinations or sub-combinations of the specific features and aspects of the embodiments may be made and still fall within the scope. The accompanying claims and their equivalents are intended to cover such forms or modifications as would fall within the scope and spirit of the disclosure.

1. A method of forming a bonded structure, the method comprising:
providing a first element having a first dielectric field region and a first conductive feature embedded in the first dielectric field region;
providing a second element having a second dielectric field region and a second conductive feature;
bonding the first dielectric field region to the second dielectric field region; and
applying inductive energy to the first element and/or second element to form a direct bond between the first conductive feature and the second conductive feature.

2. The method of claim 1, wherein the first conductive feature comprises a conductive material and a magnetic material and wherein applying inductive energy comprises using an induction heating system to heat the magnetic material.

3. (canceled)

4. The method of claim 2, wherein the magnetic material has a relative magnetic permeability of about 3 or greater.

5. (canceled)

6. (canceled)

7. (canceled)

8. (canceled)

9. The method of claim 2, wherein the magnetic material comprises a first magnetic material and wherein the second conductive feature comprises a second magnetic material.

10. (canceled)

11. The method of claim 2, wherein the first dielectric field region comprises a dielectric material, and wherein providing the first element comprises forming the first conductive feature in a cavity in the dielectric material, and wherein forming the first conductive feature comprises co-depositing the conductive material and the magnetic material.

12. The method of claim 11, wherein co-depositing the conductive material and the magnetic material comprises co-plating the conductive material and the magnetic material.

13. (canceled)

14. (canceled)

15. The method of claim 1, wherein bonding the first dielectric field region to the second dielectric field region comprises initially heating the first and second elements to form a dielectric-to-dielectric direct bond between the first and second dielectric field regions, wherein initially heating is conducted before applying inductive energy, and wherein initially heating the first and second elements comprises heating the first and second elements to a temperature of about 120 C. or less.

16. The method of claim 15, wherein the temperature comprises a first temperature and wherein applying inductive energy to the first and second elements comprises inductively heating the first conductive feature to a second temperature of about 200° C. or greater.

17. The method of claim 16, wherein a backside of the first element is at a third temperature while the first conductive feature is at the second temperature, and wherein the third temperature is about 150° C. or less.

18. The method of claim 1, wherein applying inductive energy causes the first conductive feature to expand and contact the second conductive feature.

19. (canceled)

20. (canceled)

21. A microelectronic structure, comprising:
a dielectric field region at a hybrid bonding surface of the microelectronic structure; and
a conductive feature embedded in the dielectric field region and at the hybrid bonding surface, wherein the conductive feature comprises a conductive material and a magnetic material.

22. The microelectronic structure of claim 21, wherein the conductive material comprises copper.

23. (canceled)

24. The microelectronic structure of claim 21, wherein the magnetic material has a relative magnetic permeability of about 10 or greater.

25. (canceled)

26. (canceled)

27. The microelectronic structure of claim 21, wherein an upper surface of the conductive feature is recessed below a surface of the dielectric field region.

28. (canceled)

29. The microelectronic structure of claim 21, wherein the dielectric field region comprises a dielectric material and wherein the conductive feature is formed in a cavity in the dielectric material, wherein the magnetic material at least partially lines the cavity.

30. The microelectronic structure of claim 29, wherein at least a portion of the magnetic material is between the conductive material and the dielectric material.

31. The microelectronic structure of claim 29, wherein the magnetic material comprises a material selected from the group consisting of nickel, a nickel-iron alloy, cobalt, a cobalt-zirconium alloy, a cobalt, zirconium, and tantalate alloy, Permalloy, Superpermalloy, samarium, and neodymium.

32. The microelectronic structure of claim 21, wherein the magnetic material comprises magnetic particles embedded within the conductive material.

33. (canceled)

34. The microelectronic structure of claim 32, wherein the magnetic material comprises a ceramic material.

35. The microelectronic structure of claim 34, wherein the ceramic material comprises a material selected from the group consisting of magnetite (Fe₃O₄) and nickel ferrite.

36. (canceled)

37. The microelectronic structure of claim 32, wherein the conductive feature has an upper portion that is proximal to the hybrid bonding surface and a lower portion that is distal to the hybrid bonding surface, and the magnetic particles are in the upper portion but not in the lower portion.

38. (canceled)

39. The microelectronic structure of claim 21, wherein the dielectric field region comprises a first dielectric field region and the conductive feature comprises a first conductive feature, the structure further comprising:
a first element that comprises the first dielectric field region and the first conductive feature; and
a second element hybrid bonded to the first element, wherein the second element comprises a second dielectric field region and a second conductive feature, wherein the first dielectric field region is directly bonded to the second dielectric field region, and wherein the first conductive feature is directly bonded to the second conductive feature.

40.-65. (canceled)
